(19) United States
(12) Patent Application Publication
(10) Pub. No.: US 2026/0089836 A1
(43) Pub. Date: Mar. 26, 2026

(54) PACKAGE STRUCTURE

(71) Applicant: Advanced Semiconductor Engineering, Inc., Kaohsiung (TW)

(72) Inventors: Hui-Ping JIAN, Kaohsiung (TW); Yu-Lun LU, Kaohsiung (TW)

(73) Assignee: Advanced Semiconductor Engineering, Inc., Kaohsiung (TW)

(21) Appl. No.: 18/896,736

(22) Filed: Sep. 25, 2024

(51) Int. Cl. H05K 1/02; H01L 23/00; H05K 1/18; H05K 3/34; H05K 3/46

(52) U.S. Cl. CPC H05K 1/028; H05K 1/185; H05K 1/0271; H05K 3/341; H05K 3/4644; H10W 74/10; H10W 74/15; H10W 90/724; H10W 90/734

(57) ABSTRACT

A package structure and a method of manufacturing a package structure are provided. The package structure includes a first electronic component and a flexible carrier. The first electronic component has an upper surface. The flexible carrier adjustably fastens the first electronic component. The flexible carrier defines a zone above the upper surface of the first electronic component and tapering in a direction away from the first electronic component.

### BACKGROUND

1. Field of the Disclosure The present disclosure relates to a package structure and a method of manufacturing a package structure.

### 2. Description of the Related Art

There are numerous applications for stretchable electronics. However, retaining the integrity of these devices is challenging because the difference (e.g., Young's module) between a rigid device and a stretchable carrier may result in delamination during stretching and folding.

### SUMMARY

In some embodiments, a package structure includes a first electronic component and a flexible carrier. The first electronic component has an upper surface. The flexible carrier adjustably fastens the first electronic component. The flexible carrier defines a zone above the upper surface of the first electronic component and tapering in a direction away from the first electronic component.

In some embodiments, a package structure includes a flexible carrier, a first electronic component, and a first conductive via. The first electronic component is encapsulated by the flexible carrier. The first conductive via is disposed below and electrically connected to the first electronic component. The first conductive via has a first sidewall and a second sidewall. In a cross-sectional view, a first projecting width of the first sidewall on the first electronic component is different from a second projecting width of the second sidewall on the first electronic component.

In some embodiments, a package structure includes a flexible carrier and a first electronic component. The first electronic component is encapsulated by the flexible carrier. When the package structure is applied with a deformation force, the first electronic component and the flexible carrier define a first cavity therebetween.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 is a cross-sectional view of a package structure according to some embodiments of the present disclosure.

FIG. 2A is a cross-sectional view of a package structure being applied with a deformation force according to some embodiments of the present disclosure.

FIG. 2B is a cross-sectional view of a package structure being applied with a deformation force according to some embodiments of the present disclosure.

FIG. 3 is a cross-sectional view of a package structure being applied with a deformation force according to some embodiments of the present disclosure.

FIG. 4 is a cross-sectional view of a package structure according to some embodiments of the present disclosure.

FIG. 4A illustrates an enlarged cross-sectional view of a box B11 in FIG. 4.

FIG. 4B illustrates an enlarged cross-sectional view of a box B12 in FIG. 4.

FIGS. 5A, 5B, 5C, 5D, 5E, 5F, 5G, 5H, and 5I illustrate one or more stages of an example of a method for manufacturing a package structure according to some embodiments of the present disclosure.

FIGS. 6A, 6B, 6C, and 6D each represent a top view of a structure in FIGS. 5G and 5H.

FIG. 6E illustrates a perspective view of a structure in FIG. 6D.

FIG. 7 is a cross-sectional view of a package structure according to some embodiments of the present disclosure.

FIG. 8 is a perspective view of a box B1 in FIG. 7.

FIG. 9A is a cross-sectional view of a package structure being applied with a deformation force according to some embodiments of the present disclosure.

FIG. 9B is a cross-sectional view of a package structure being applied with a deformation force according to some embodiments of the present disclosure.

FIG. 10 is a cross-sectional view of a package structure being applied with a deformation force according to some embodiments of the present disclosure.

FIG. 11 is a cross-sectional view of a package structure according to some embodiments of the present disclosure.

FIG. 11A illustrates an enlarged cross-sectional view of a box B21 in FIG. 11.

FIG. 11B illustrates an enlarged cross-sectional view of a box B22 in FIG. 11.

FIGS. 12A, 12B, 12C, 12D, 12E, 12F, 12G, 12H, and 12I illustrate one or more stages of an example of a method for manufacturing a package structure according to some embodiments of the present disclosure.

FIGS. 13A, 13B, 13C, and 13D each represent a top view of a structure in FIGS. 12G and 12H.

FIG. 13E illustrates a perspective view of a structure in FIG. 13D.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

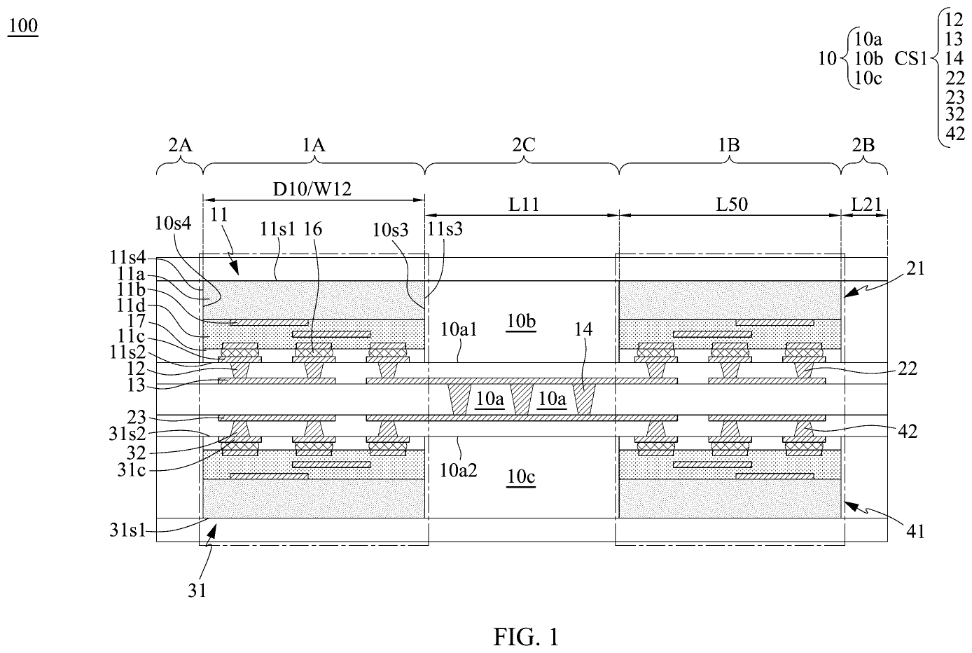

FIG. 1 is a cross-sectional view of a package structure 100 according to some embodiments of the present disclosure. The package structure 100 may include a carrier 10, an electronic component 11, a plurality of connection elements 16, an underfill 17, an electronic component 21, a connection element 26, an underfill 27, an electronic component 31, an electronic component 41, and a circuit structure CS1.

The carrier (or a flexible carrier) 10 may be pliable. For example, the outline of the carrier 10 may be bendable, twistable, and/or stretchable. The carrier 10 may include a pliable material, a flexible material, or a soft material. The carrier 10 may include, but is not limited to, thermosetting polymer or thermoplastic polymer. The carrier 10 may include, but is not limited to, silicone rubber. In some embodiments, the carrier 10 may be or include, for example, one or more of a printed circuit board, such as a paper-based copper foil laminate, a composite copper foil laminate, a polymer-impregnated glass-fiber-based copper foil laminate, and so on.

The carrier 10 may include a portion 10a, a portion 10b disposed over the portion 10a, and a portion 10c disposed below the portion 10a. The carrier 10 may be formed through a series of deposition processes. In some embodiments, the portion 10a may be formed prior to the portion 10b and the portion 10c. For example, the portion 10a may be formed prior to the mounting (e.g., surface mount technology (SMT) process) of the electronic components 11, 21, 31, and 41. The portion 10a may be referred to as a substrate (a carrier) for supporting the electronic components 11, 21, 31, and 41. The portion 10a may have a first surface 10a1 supporting the electronic components 11 and 21. The electronic components 11 and 21 may be disposed above the first surface 10a1 of the portion (or the substrate) 10a. The portion 10a may have a second surface 110a2 opposite to the first surface 10a1 and supporting the electronic components 31 and 41. The electronic components 31 and 41 may be disposed below the second surface 10a2 of the portion (or the substrate) 10a. The portion 10b may be referred to as an encapsulating layer for encapsulating the electronic components 11 and 21. The portion 10c may be referred to as an encapsulating layer for encapsulating the electronic components 31 and 41.

The portion 10a, 10b, or 10c may have interfaces therein if its material is thermosetting polymer. In some embodiments, the portion 10a, 10b, or 10c may have no interface therein if its material is thermoplastic polymer.

The electronic component 11 may be electrically connected to the electronic component 21, 31, or 41 through the circuit structure CS1. Similarly, the electronic component 21, 31, or 41 may be respectively electrically connected to the other electronic components. The circuit structure CS1 may be embedded in the portion 10a of the carrier 10.

The circuit structure CS1 may include a plurality of conductive vias 12, a conductive layer 13, a plurality of conductive vias 14, a plurality of conductive vias 22, a conductive layer 23, a plurality of conductive vias 32, and a plurality of conductive vias 42. The conductive vias 12 may be connected to the conductive layer 13. The conductive vias 22 may be connected to the conductive layer 13. The conductive layer 13 may be connected to the conductive vias 14. The conductive layer 13 may be disposed between the conductive vias 12 and the conductive vias 14. The conductive vias 32 may be connected to the conductive layer 23. The conductive vias 42 may be connected to the conductive layer 23. The conductive layer 23 may be connected to the conductive vias 14. The conductive layer 23 may be disposed between the conductive vias 22 and the conductive vias 14. The conductive vias 12 may taper in a direction opposite to the conductive vias 32. The conductive vias 22 may taper in a direction opposite to the conductive vias 42. The conductive vias 12 and the conductive vias 14 may taper in the same direction. The conductive vias 32 and the conductive vias 14 may taper in different directions.

In some embodiments, the conductive layers 13 and 23 may be formed of metal or metal alloy. The conductive layers 13 and 23 may include metal, such as copper, gold, silver, aluminum, titanium, tantalum, or the like. In some embodiments, the conductive vias 12, 22, 32, 42 and 14 may be formed of metal or metal alloy. The conductive vias 12, 22, 32, 42 and 14 may include metal, such as copper, gold, silver, aluminum, titanium, tantalum, or the like. The conductive layers 13 and 23 and the conductive vias 12, 22, 32, 42 and 14 may each include a seed layer. The material of the conductive layers 13 and 23 and the conductive vias 12, 22, 32, 42 and 14 may be ductile and malleable. The conductive layers 13 and 23 and the conductive vias 12, 22, 32, 42 and 14 may be pliable, bendable, twistable, and/or stretchable.

The portion 10b may cover, encapsulate, or surround the electronic components 11 and 21. The electronic component 11 may be mounted to the portion 10a of the carrier 10 after the formation of the portion 10b. The portion 10b may define a space having a width narrower than that of the electronic component 11. The carrier 10 may be temporarily stretched to enlarge the space for accommodating the electronic component 11. The carrier 10 may adjustably fasten the electronic component 11. The carrier 10 may have a first inner sidewall 10s3 and a second inner sidewall 10s4 facing the electronic component 11. A distance D10 between the first inner sidewall 10s3 and the second inner sidewall 10s4 may be adjustable based on a width W12 of the electronic component 11. The electronic component 11 may be tightly fixed by the portion 10b (or the encapsulating layer) of the carrier 10. Similarly, the portion 10b may define another space for accommodating the electronic component 21. The electronic component 21 may be tightly fixed by the portion 10b (or the encapsulating layer) of the carrier 10.

The electronic component 11 may be encapsulated by the carrier 10. The electronic component 11 may include a main portion 11a, a circuit layer 11b, a plurality of conductive pads 11c, dielectric layer 11d, the connection elements 16, and the underfill 17. The electronic component 11 may include a system in package (SiP). The electronic component 11 may be relatively rigid, e.g., compared to the carrier 10.

The main portion 11a may be disposed over the circuit layer 11b. The main portion 11a may include one or more semiconductor dies and an encapsulating layer encapsulating the semiconductor dies. The encapsulating layer of the main portion 11a may include an epoxy resin including fillers, a molding compound (e.g., an epoxy molding compound or other molding compound), polyimide, a phenolic compound or material, a material including silicone dispersed therein, or a combination thereof. The semiconductor dies may be electrically connected to the circuit layer 11b. The circuit layer 11b may include a fan-out structure. The circuit layer 11b may include a redistribution layer. The circuit layer 11b may be embedded in the dielectric layer 11d. The underfill 17 may be disposed below the dielectric layer 11d. The connection elements 16 may be covered, surrounded, or encapsulated by the underfill 17. The conductive pads 11c may be electrically connected to the circuit layer 11b through the connection elements 16.

The connection elements 16 may include solder balls, controlled collapse chip connection (C4) bumps, a ball grid array (BGA), or a land grid array (LGA). The underfill 17 may include an epoxy resin including fillers, a molding compound (e.g., an epoxy molding compound or another molding compound), polyimide, a phenolic compound or material, a material including silicone dispersed therein, or a combination thereof.

The conductive pads 11c may be connected to the conductive vias 12. During the mounting process of the electronic component 11, the conductive pads 11c may be mounted to the conductive vias 12. The conductive pads 11c may be metallically bonded to the conductive vias 12.

The electronic component 11 may have an upper surface (or an active surface) 11s1, a lower surface 11s2 opposite to the upper surface 11s1, a lateral surface 11s3 extending between the upper surface 11s1 and the lower surface 11s2, and a lateral surface 11s4 opposite to the lateral surface 11s3.

The lower surface 11s2 may be inseparably connected to the portion 10a of the carrier 10. In some embodiments, the conductive pads 11c are at the lower surface 11s2 and metallically bonded to the conductive vias 12. As such, the connection between the lower surface 11s2 and the carrier 10 may be inseparable while the package structure 100 is stretched, folded, or twisted.

In some embodiments, the lateral surface 11s3 and/or the lateral surface 11s4 may be detachably connected to the portion 10b of the carrier 10. The lateral surface 11s3 and/or the lateral surface 11s4 may be temporarily spaced apart from (or disconnected from) the portion 10b of the carrier 10 while the package structure 100 is stretched, folded, or twisted. The detachable connection between the lateral surface 11s3 (or the lateral surface 11s4) and the carrier 10 can absorb the stress induced by the stretching, folding, or twisting. The electronic component 21 may have similar structures and elements to the electronic component 11. The electronic component 21 may be relatively rigid, e.g., compared to the carrier 10. The electronic component 21 may be connected to the portion 10a and the portion 10b in a manner similar to how the electronic component 11 is connected. In some embodiments, the lateral surfaces of the electronic component 21 may be detachably connected to the portion 10b of the carrier 10.

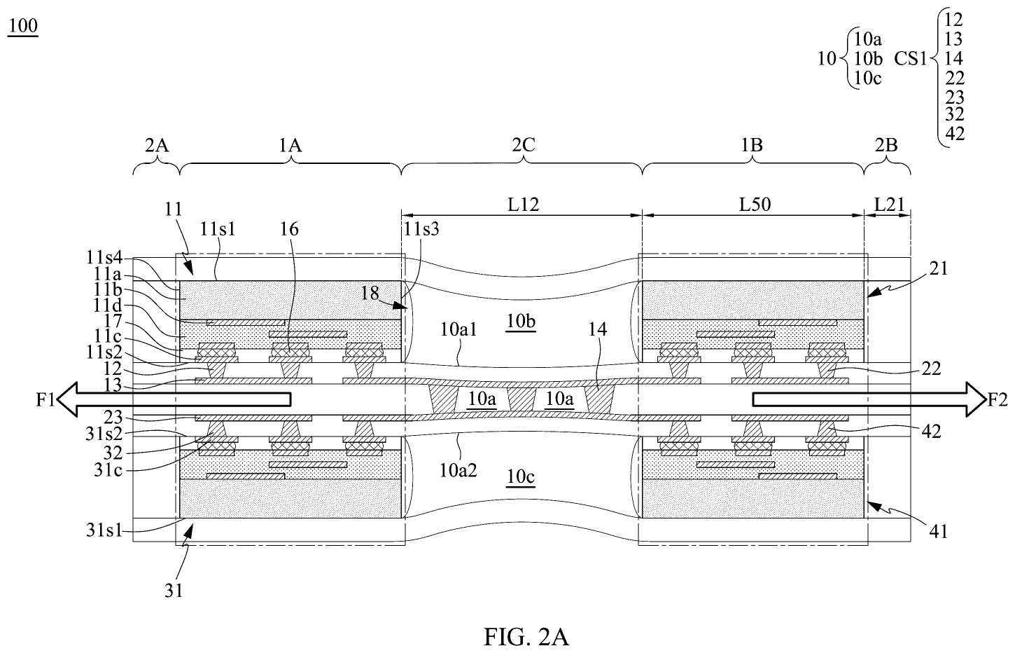

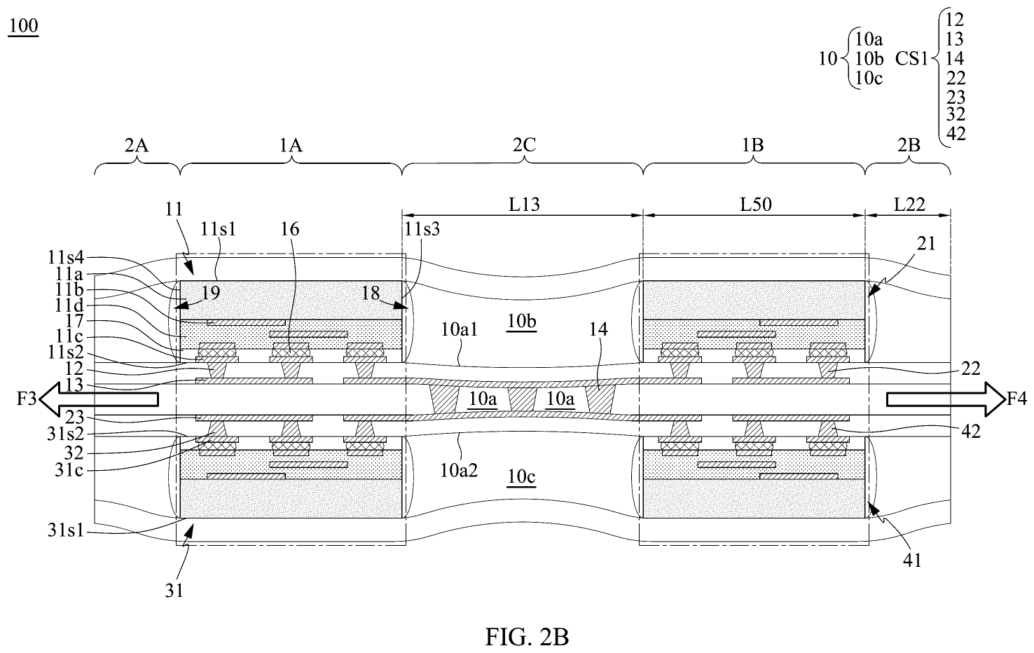

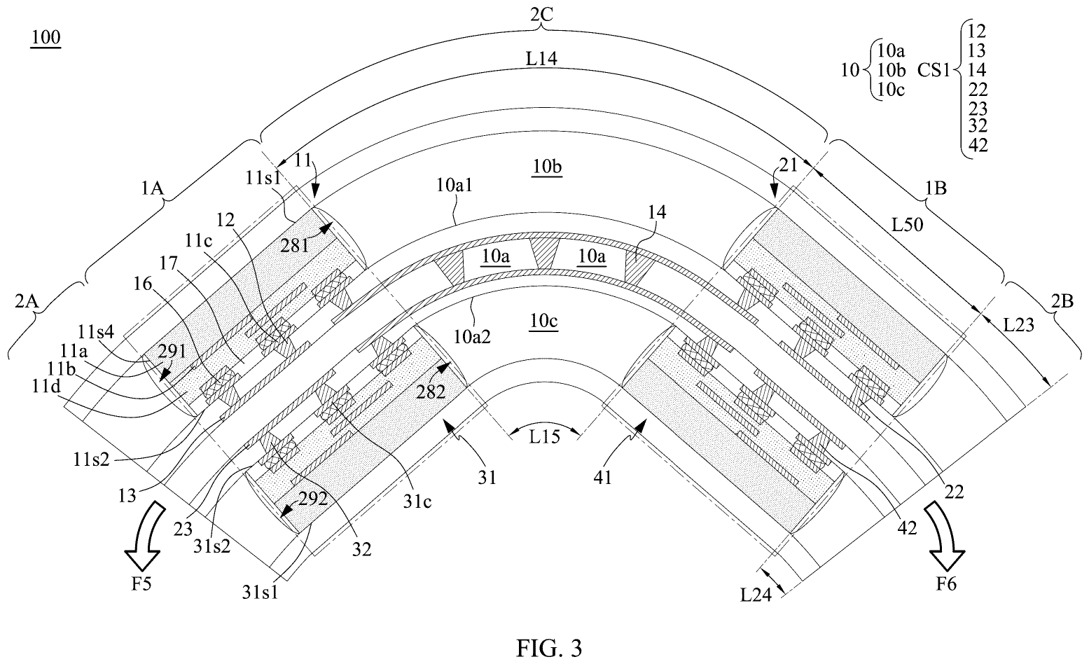

The majority of the induced stress may be applied to the portion 10b rather than the electronic component 11 and/or 21. The lateral surfaces 11s3 and 11s4 are detachably connected to the portion 10b. The portion 10b may be deformed to have a cavity (or a void) along the lateral surface 11s3 (or the lateral surface 11s4) of the electronic component 11 (or the electronic component 21), thereby neutralizing (or dissipating) the induced stress (for details, see the descriptions related to FIGS. 2A, 2B, and 3). As such, the electronic component 11 and/or 21 can be tightly connected to the portion 10a of the carrier 10 (or the circuit structure CS1) without delamination. The electrical connection between the electronic component 11 (or 21) and the circuit structure CS1 can be retained.

The electronic component 31 may have structures and elements similar to those of the electronic component 11. The electronic component 31 may be relatively rigid, e.g., compared to the carrier 10. The electronic component 31 may have an upper surface (or an active surface) 31s2 and a lower surface 31s1 opposite to the upper surface 31s2. The active surface 11s1 of the electronic component 11 may face the active surface 31s1 of the electronic component 31. The electronic component 31 may include a plurality of conductive pads 31c connected to the conductive vias 32.

The electronic component 41 may have structures and elements similar to those of the electronic component 11. The electronic component 41 may be relatively rigid, e.g., compared to the carrier 10. The electronic component 31 may be opposite to the electronic component 11 with respect to the portion 10a. The electronic component 41 may be opposite to the electronic component 21 with respect to the portion 10a.

The electronic components 11, 21, 31, and 41 may be responsible for different functions of the package structure 100. In some embodiments, the electronic component 11 may include a graphic processing unit (GPU); the electronic component 21 may include a central processing unit (CPU); the electronic component 31 may include a wireless communication module; the electronic component 41 may include a sensor module.

The portion 10c may cover, encapsulate, or surround the electronic components 31 and 41. The electronic component 31 may be mounted to the portion 10a of the carrier 10 after the formation of the portion 10c. The portion 10c may define a space having a width narrower than that of the electronic component 31. The carrier 10 may be temporarily stretched to enlarge the space for accommodating the electronic component 31. The electronic component 31 may be tightly fixed by the portion 10c (or the encapsulating layer) of the carrier 10. Similarly, the portion 10c may define another space for accommodating the electronic component 41. The electronic component 41 may be tightly fixed by the portion 10c (or the encapsulating layer) of the carrier 10.

The majority of the induced stress may be applied to the portion 10c rather than the electronic component 31 and/or 41. In some embodiments, the lateral surfaces of the electronic component 31 (or the electronic component 41) may be detachably connected to the portion 10c of the carrier 10. The portion 10c may be deformed to have a cavity (or a void) along the lateral surface of the electronic component 31 (or the electronic component 41), thereby neutralizing (or dissipating) the induced stress (for details, see the descriptions related to FIGS. 2A, 2B, and 3). As such, the electronic component 31 and/or 41 can be tightly connected to the portion 10a of the carrier 10 (or the circuit structure CS1) without delamination. The electrical connection between the electronic component 31 (or 41) and the circuit structure CS1 can be retained.

In some embodiments, the package structure 100 may have a region 1A, a region 1B, a region 2A, a region 2B, and a region 2C. The region 1A may include the electronic component 11 and the electronic component 31. The region 1B may include the electronic component 21 and the electronic component 41. The region 2C may be disposed between the region 1A and the region 1B. The region 2C may be adjacent to the region 1A and/or the region 1B. The region 2A may be adjacent to the region 1A but spaced apart from the region 2C. The region 2B may be adjacent to the region 1B but spaced apart from the region 2C. The regions 1A and 1B may have a length L50 in a direction along a long side of the package structure 100. In some embodiments, the regions 1A and 1B may have different lengths in case the electronic component 11 and the electronic component 21 have different sizes. As shown in FIG. 1, the package structure 100 is in an initial state when no deformation force is applied thereto. The regions 2A and 2B may have a length L21 in a direction along the long side of the package structure 100. The region 2C may have a length L11 in a direction along the long side of the package structure 100.

The regions 1A and 1B may each include rigid elements (e.g., the electronic component 11, 21, 31, or 41). The regions 1A and 1B may have a relatively large pliability. The regions 2A, 2B, and 2C may include no rigid elements. The regions 2A, 2B, and 2C may each include a part of the circuit structure CS1 and/or a part of the carrier 10. The regions 2A, 2B, and 2C may each have a relatively low pliability. The region 2C may have a pliability greater than a pliability of the region 1A or the region 1B. In some embodiments, when the package structure 100 is folded or stretched, a curvature of the region 2C may be greater than a curvature of the region 1A or the region 1B. The region 2A or 2B may have a pliability greater than a pliability of the region 1A or the region 1B. In some embodiments, the regions 2A, 2B, and 2C may have a larger deformation than that of the regions 1A and 2B while the package structure 100 is applied with a deformation force (for details, see the descriptions related to FIGS. 2A, 2B, and 3).

FIG. 2A is a cross-sectional view of a package structure (e.g., the package structure 100) being applied with a deformation force according to some embodiments of the present disclosure. The package structure 100 is in a stretching state. In some embodiments, the package structure 100 may be stretched in a direction parallel to a long side of the package structure 100. The package structure 100 may be applied with a deformation force F1 and a deformation force F2 having a direction opposite to the deformation force F1. The point of application of the deformation force F1 may be the region 1A. The point of application of the deformation force F2 may be the region 1B. In some embodiments, the package structure 100 may be stretched by hand or with clamps.

During the application of the deformation force F1 and/or the deformation force F2, the region 2C may be stretched such that the region 2C may have a length L12 greater than the length L11 of FIG. 1 (when the package structure 100 is in the initial state). The length L12 may be positively correlated to a level of the deformation force F1 and/or F2. The length L50 of the region 1A or 1B may be substantially the same as it was in the initial state. The part of the carrier 10 in the region 2C may be stretched (or have tensile stress) to have a necking profile. The material of the circuit structure CS1 may be ductile and malleable. The part of the circuit structure CS1 (e.g., the conductive vias 14 and the conductive layers 13 and 23) may be stretched (or have tensile stress) to have a curved shape. The part of the circuit structure CS1 in the region 2C can be seamlessly continuous with that in the region 1A or 1B.

In some embodiments, when the package structure 100 is applied with the deformation force F1 or F2, the electronic component 11 and the carrier 10 may define a cavity (or a void) 18 therebetween. The void may be an empty space. The cavity 18 may be between the lateral surface 11s3 of the electronic component 11 and the portion 10b of the carrier 10. The cavity 18 may have a first sidewall defined by the lateral surface 11s3. The cavity 18 may have a semicircular or semi-oval shape in a cross-sectional view. The volume of the cavity 18 may be positively correlated with a level of the deformation force F1 or F2. During the application of the deformation force F1 or F2, the portion 10b may be spaced apart from the electronic component 11 by the cavity 18. When the deformation force F1 or F2 is removed, the portion 10b is in direct contact with the first electronic component.

Similarly, each of the electronic components 21, 31, and 41 and the carrier 10 may define the cavity 18 therebetween. The cavity 18 may be between the inner lateral surface of the electronic component 21 and the portion 10b of the carrier 10. The cavity 18 may be between each of the inner lateral surfaces of the electronic components 31 and 41 and the portion 10c of the carrier 01. The cavity 18 may be in the region 2C.

The lateral surface 11s3 may be detachably connected to the portion 10b of the carrier 10. In some embodiments, the inner lateral surface of the electronic component 21 may be detachably connected to the portion 10b of the carrier 10. In some embodiments, the inner lateral surfaces of the electronic components 31 and 41 may be detachably connected to the portion 10c of the carrier 10. The lateral surface 11s3 may be temporarily spaced apart from (or disconnected from) the portion 10b of the carrier 10 while the package structure 100 is stretched, folded, or twisted. The detachable connection between the lateral surface 11s3 and the carrier 10 can absorb the stress induced by the stretching, folding, or twisting.

The majority of the induced stress may be applied to the portion 10b and the portion 10c rather than the electronic components 11, 21, 31, and 41. The portion 10b and the portion 10c may neutralize (or dissipate) the induced stress by temporarily creating the cavity 18. The electronic components 11, 21, 31, and 41 may not be dragged by the induced stress or may only be dragged to a minor extent. As such, the electronic components 11, 21, 31, and 41 can be tightly connected to the portion 10a of the carrier 10 (or the circuit structure CS1) without delamination. The electrical connection between the electronic component 11 (or 21, 31, 41) and the circuit structure CS1 can be retained.

FIG. 2B is a cross-sectional view of a package structure (e.g., the package structure 100) being applied with a deformation force according to some embodiments of the present disclosure. The package structure 100 is in a stretching state. In some embodiments, the package structure 100 may be stretched in a direction parallel to a long side of the package structure 100. The package structure 100 may be applied with a deformation force F3 and a deformation force F4 having a direction opposite to the deformation force F3. The point of application of the deformation force F3 may be the region 2A. The point of application of the deformation force F4 may be the region 2B. In some embodiments, the package structure 100 may be stretched by hand or with clamps.

During the application of the deformation force F3 and/or the deformation force F4, the region 2C may be stretched such that the region 2C may have a length L13 greater than the length L11 of FIG. 1 (when the package structure 100 is in the initial state). The length L13 may be positively correlated to a level of the deformation force F3 and/or F4. During the application of the deformation force F3 and/or the deformation force F4, the regions 2A and 2B may be stretched such that the regions 2A and 2B may have a length L22 greater than the length L21 of FIG. 1 (when the package structure 100 is in the initial state). The length L22 may be positively correlated to a level of the deformation force F3 and/or F4. The length L50 of the region 1A or 1B may be substantially the same as it was in the initial state. The part of the carrier 10 in the region 2C may be stretched (or have tensile stress) to have a necking profile. The material of the circuit structure CS1 may be ductile and malleable. The part of the circuit structure CS1 (e.g., the conductive vias 14 and the conductive layers 13 and 23) may be stretched (or have tensile stress) to have a curved shape. The part of the circuit structure CS1 in the region 2C can be seamlessly continuous with that in the region 1A or 1B. The part of the carrier 10 in the regions 2A and 2B may be stretched (or have tensile stress).

In some embodiments, when the package structure 100 is applied with the deformation force F3 or F4, the electronic component 11 and the carrier 10 may define the cavity 18 and a cavity (or a void) 19 therebetween. The descriptions of the cavity 18 have been previously discussed. The cavity 19 may be between the lateral surface 11s4 of the electronic component 11 and the portion 10b of the carrier 10. The cavity 19 may have a second sidewall defined by the lateral surface 11s4. The cavity 19 may have a semicircular or semi-oval shape in a cross-sectional view. The volume of the cavity 19 may be positively correlated with a level of the deformation force F3 or F4. During the application of the deformation force F3 or F4, the portion 10b may be spaced apart from the electronic component 11 by the cavity 19. The electronic component 11 may be surrounded by the cavity 18 and/or the cavity 19. When the deformation force F3 or F4 is removed, the portion 10b is in direct contact with the first electronic component.

Similarly, each of the electronic components 21, 31, and 41 and the carrier 10 may define the cavity 19 therebetween. The cavity 19 may be between the outer lateral surface of the electronic component 21 and the portion 10b of the carrier 10. The cavity 19 may be between each of the outer lateral surfaces of the electronic components 31 and 41 and the portion 10c of the carrier 10. The cavity 19 may be in the region 2A and the region 2B.

The lateral surfaces 11s3 and 11s4 may be detachably connected to the portion 10b of the carrier 10. In some embodiments, the inner and outer lateral surfaces of the electronic component 21 may be detachably connected to the portion 10b of the carrier 10. In some embodiments, the inner and outer lateral surfaces of the electronic components 31 and 41 may be detachably connected to the portion 10c of the carrier 10. The lateral surfaces 11s3 and 11s4 may be temporarily spaced apart from (or disconnected from) the portion 10b of the carrier 10 while the package structure 100 is stretched, folded, or twisted. The detachable connection between the lateral surfaces 11s3 and 11s4 and the carrier 10 can absorb the stress induced by the stretching, folding, or twisting.

The majority of the induced stress may be applied to the portions 10b and 10c rather than the electronic components 11, 21, 31, and 41. The portions 10b and 10c may neutralize (or dissipate) the induced stress by temporarily creating the cavity 18 and the cavity 19. The electronic components 11, 21, 31, and 41 may not be dragged by the induced stress or may only be dragged to a minor extent. As such, the electronic components 11, 21, 31, and 41 can be tightly connected to the portion 10a of the carrier 10 (or the circuit structure CS1) without delamination. The electrical connection between the electronic component 11 (or 21, 31, 41) and the circuit structure CS1 can be retained.

FIG. 3 is a cross-sectional view of a package structure (e.g., the package structure 100) being applied with a deformation force according to some embodiments of the present disclosure. The package structure 100 is in a folding state (or a bending or twisting state). In some embodiments, the package structure 100 may be folded. The package structure 100 may be applied with a deformation force F5 and a deformation force F6. The directions of the deformation forces F5 and F6 form an angle less than 180 degrees. The point of application of the deformation force F5 may be the region 2A. The point of application of the deformation force F6 may be the region 2B. In some embodiments, the package structure 100 may be folded by hand or with clamps.

During the application of the deformation force F5 and/or the deformation force F6, the region 2C may be folded such that the region 2C may have a length L14 greater than the length L11 of FIG. 1 (when the package structure 100 is in the initial state). In the region 2C, the length L15 may be opposite to the length L14 and smaller than the length L11. The region 2C may have a longer side (the length L15) and a shorter side (the length L14). The length L14 may be positively correlated to a level of the deformation force F5 and/or F6. The length L15 may be negatively correlated to a level of the deformation force F5 and/or F6. During the application of the deformation force F5 and/or the deformation force F6, the regions 2A and 2B may be folded such that the regions 2A and 2B may have a length L23 greater than the length L21 of FIG. 1 (when the package structure 100 is in the initial state). In the region 2C, the length L24 may be opposite to the length L23 and smaller than the length L21. The regions 2A and 2B may have a longer side (the length L23) and a shorter side (the length L24). The length L23 may be positively correlated to a level of the deformation force F5 and/or F6. The length L24 may be negatively correlated to a level of the deformation force F5 and/or F6. The length L50 of the region 1A or 1B may be substantially the same as it was in the initial state.

The part of the carrier 10 in the region 2C may be folded (or have tensile stress at the longer side and compressive stress at the shorter side) to have a curved profile. The material of the circuit structure CS1 may be ductile and malleable. The part of the circuit structure CS1 (e.g., the conductive vias 14 and the conductive layers 13 and 23) may be folded (or bended) to have a curved shape. The part of the circuit structure CS1 in the region 2C can be seamlessly continuous with that in the region 1A or 1B. The part of the carrier 10 in the regions 2A and 2B may be folded (or bended).

In some embodiments, when the package structure 100 is applied with the deformation force F5 or F6, the electronic component 11 and the carrier 10 may define a cavity 281 and a cavity 291 therebetween. The cavity 281 may be between the lateral surface 11s3 of the electronic component 11 and the portion 10b of the carrier 10. The cavity 291 may be between the lateral surface 11s4 of the electronic component 11 and the portion 10b of the carrier 10. The cavity 281 and the cavity 291 may each have a semicircular or semi-oval shape in a cross-sectional view. The volume of the cavity 281 and the cavity 291 may be positively correlated with a level of the deformation force F5 or F6. During the application of the deformation force F5 or F6, the portion 10b may be spaced apart from the electronic component 11 by the cavity 281. During the application of the deformation force F5 or F6, the portion 10b may be spaced apart from the electronic component 11 by the cavity 291. When the deformation force F5 or F6 is removed, the portion 10b is in direct contact with the electronic component 11.

In some embodiments, the electronic component 31 and the carrier 10 may define a cavity 282 and a cavity 292 therebetween. The cavity 282 may be between the inner lateral surface of the electronic component 31 and the portion 10c of the carrier 10. The cavity 292 may be between the outer lateral surface of the electronic component 31 and the portion 10b of the carrier 10. The area around the electronic component 11 may have a relatively large amount of stress compared to the area around the electronic component 31 during the application of the deformation forces F5 and F6. The portion 10b adjacent to the electronic component 11 may be deformed to a great extent compared to the portion adjacent to the electronic component 31. The size of the cavity 281 may be larger than that of the cavity 282. The size of the cavity 291 may be larger than that of the cavity 292.

Similarly, the electronic component 21 and the carrier 10 may define the cavity 281 therebetween. The cavity 281 may be between the inner lateral surface of the electronic component 21 and the portion 10b of the carrier 10. The cavity 281 may be in the region 2C. The electronic component 21 and the carrier 10 may define the cavity 291 therebetween. The cavity 291 may be between the outer lateral surface of the electronic component 21 and the portion 10b of the carrier 10. The cavity 291 may be in the region 2A and the region 2B.

Similarly, the electronic component 41 and the carrier 10 may define the cavity 282 therebetween. The cavity 282 may be between the inner lateral surface of the electronic component 41 and the portion 10c of the carrier 10. The cavity 282 may be in the region 2C. The electronic component 41 and the carrier 10 may define the cavity 292 therebetween. The cavity 292 may be between the outer lateral surface of the electronic component 41 and the portion 10c of the carrier 10. The cavity 292 may be in the region 2A and the region 2B.

The lateral surfaces of the electronic components 11 and 21 may be detachably connected to the portion 10b of the carrier 10. The lateral surfaces of the electronic components 31 and 41 may be detachably connected to the portion 10c of the carrier 10. The lateral surfaces may be temporarily spaced apart from (or disconnected from) the portion 10b (and the portion 10c) of the carrier 10 while the package structure 100 is stretched, folded, or twisted. The detachable connection between the lateral surfaces of the electronic components 11, 21, 31, and 41 and the carrier 10 can absorb the stress induced by the stretching, folding, or twisting.

The majority of the induced stress may be applied to the portion 10b and the portion 10c rather than the electronic components 11, 21, 31, and 41. The portion 10b and the portion 10c may neutralize (or dissipate) the induced stress by temporarily creating the cavities 281, 282, 291, and 292. The electronic components 11, 21, 31, and 41 may not be dragged by the induced stress or may only be dragged to a minor extent. As such, the electronic components 11, 21, 31, and 41 can be tightly connected to the portion 10a of the carrier 10 (or the circuit structure CS1) without delamination. The electrical connection between the electronic component 11 (or 21, 31, 41) and the circuit structure CS1 can be retained.

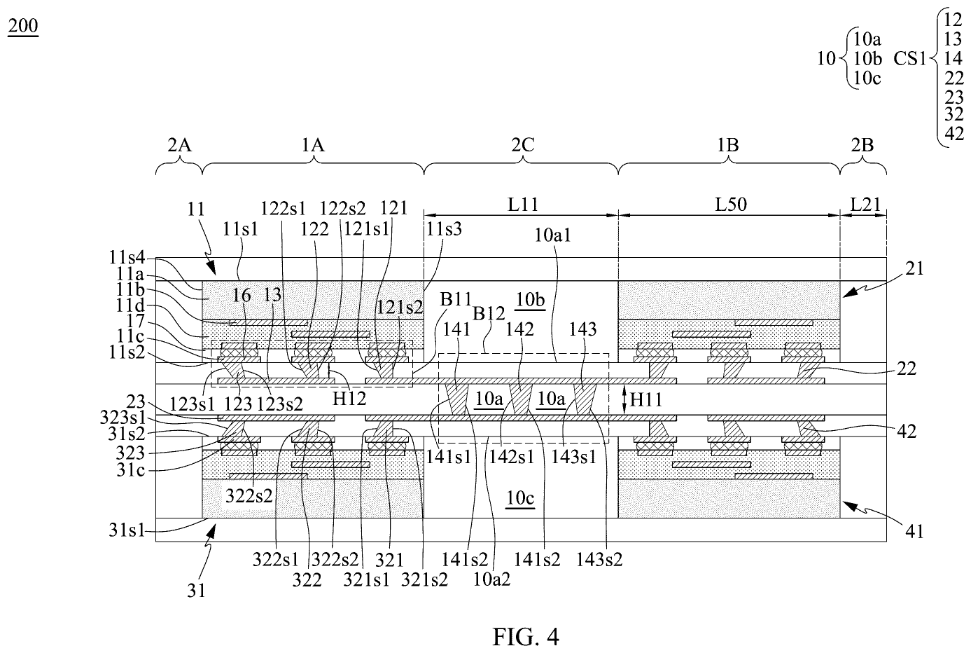

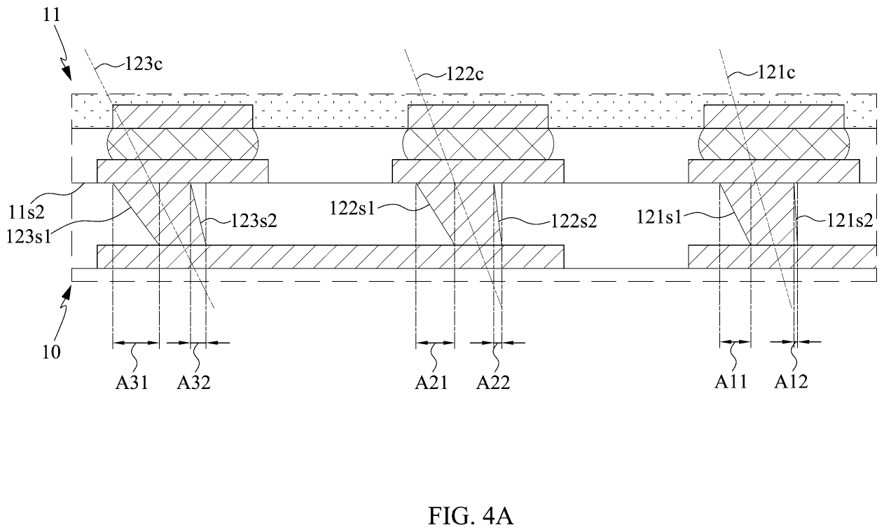

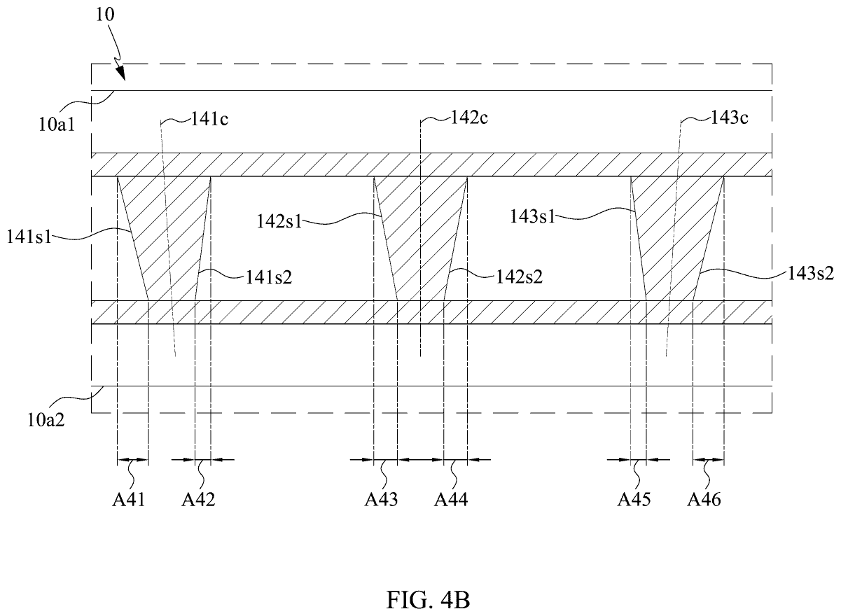

FIG. 4 is a cross-sectional view of a package structure 200 according to some embodiments of the present disclosure. The package structure 200 in FIG. 4 is similar to the package structure 100 in FIG. 1. Therefore, some detailed descriptions may refer to corresponding preceding paragraphs and are not repeated hereinafter for conciseness, with differences therebetween as follows.

As previously discussed, the carrier 10 may be temporarily stretched to enlarge the space for accommodating the electronic component 11. The electronic component 11 may be tightly fixed by the portion 10b (or the encapsulating layer) of the carrier 10. The circuit structure CS1 embedded in the carrier 10 may deform when the carrier 10 is stretched. In some embodiments, the pitch of the conductive vias of the circuit structure CS1 may be enlarged and the profile of the conductive vias may be tilted. When the electronic component 11 is mounted to the portion 10a of the carrier 10, the conductive pads 11c of the electronic component 11 may be metallically bonded to the circuit structure CS1 (e.g., conductive vias under the electronic component 11). In some embodiments, the titled profile of the conductive vias may be retained. The circuit structure CS1 may have asymmetrical conductive vias 121, 122, and 123 disposed below and electrically connected to the electronic component 11.

The conductive via 121 may have a first sidewall 121s1 with a first slope and a second sidewall 121s2 with a second slope, and a first absolute value of the first slope is different from a second absolute value of the second slope. The first sidewall 121s1 is closer to the lateral surface 11s4 of the electronic component 11 than the second sidewall 121s2. The second absolute value of the second sidewall 121s2 may be greater than the first absolute value of the first sidewall 121s1.

The conductive via 122 may be more tilted than the conductive via 121. The conductive via 123 may be more tilted than the conductive vias 121 and 122. The conductive via 123 may have a third sidewall 123s1 with a third slope and a fourth sidewall 123s2 with a fourth slope, and a third absolute value of the third slope is less than the first absolute value of the first sidewall 121s1 and a fourth absolute value of the fourth slope is less than the second absolute value of the second sidewall 121s2.

FIG. 4A illustrates an enlarged cross-sectional view of a box B11 in FIG. 4.

As shown in FIG. 4A, the first sidewall 121s1 has a first projecting width A11 on the electronic component 11 (or the lower surface 11s2) and the second sidewall 121s2 has a second projecting width A12 on the electronic component 11 (or the lower surface 11s2). Owing to the asymmetrical profile of the conductive via 121, the first projecting width A11 is different from the second projecting width A12. In some embodiments, the first projecting width A11 may be greater than the second projecting width A12.

The third sidewall 123s1 has a third projecting width A31 on the electronic component 11 (or the lower surface 11s2) and the fourth sidewall 123s2 has a fourth projecting width A32 on the electronic component 11 (or the lower surface 11s2). Owing to the asymmetrical profile of the conductive via 123, the third projecting width A31 is different from the fourth projecting width A32. In some embodiments, the third projecting width A31 may be greater than the fourth projecting width A32.

The conductive via 122 may have a fifth sidewall 122s1 and a sixth sidewall 122s2. The fifth sidewall 122s1 has a sixth projecting width A21 on the electronic component 11 (or the lower surface 11s2) and the sixth sidewall 122s2 has a sixth projecting width A22 on the electronic component 11 (or the lower surface 11s2). Owing to the asymmetrical profile of the conductive via 122, the fifth projecting width A21 is different from the sixth projecting width A22. In some embodiments, the fifth projecting width A21 may be greater than the sixth projecting width A22.

The conductive vias 121, 122, and 123 may have central axes 121c, 122c, and 123c, respectively. The central axes 121c, 122c, and 123c may be non-perpendicular to the lower surface 11s2 of the electronic component 11. The central axes 121c, 122c, and 123c may be non-parallel to each other.

Referring back to FIG. 4, the circuit structure CS1 may have asymmetrical conductive vias 321, 322, and 323 disposed above and electrically connected to the electronic component 31. The conductive vias 321, 322, and 232 may taper in a direction opposite to the conductive vias 121, 122, and 123. The conductive via 322 may be more tilted than the conductive via 321. The conductive via 323 may be more tilted than the conductive vias 321 and 322.

The conductive via 321 may have a first sidewall 321s1 with a first slope and a second sidewall 321s2 with a second slope, and a first absolute value of the first slope is different from a second absolute value of the second slope. The first sidewall 321s1 is closer to the lateral surface 11s4 of the electronic component 11 than the second sidewall 321s2. The second absolute value of the second sidewall 321s2 may be greater than the first absolute value of the first sidewall 321s1.

The conductive via 322 may be more tilted than the conductive via 321. The conductive via 323 may be more tilted than the conductive vias 321 and 322. The conductive via 323 may have a third sidewall 323s1 with a third slope and a fourth sidewall 323s2 with a fourth slope, and a third absolute value of the third slope is less than the first absolute value of the first sidewall 321s1 and a fourth absolute value of the fourth slope is less than the second absolute value of the second sidewall 321s2.

The conductive vias 321, 322, and 323 may have similar structures to the conductive vias 121, 122, and 123 as shown in FIG. 4A. For example, a sidewall (e.g., 321s1, 322s1, and 323s1) of each of the conductive vias 321, 322, and 323 may have a projecting width on the electronic component 31 that is different from a projecting width of the other sidewall (e.g., 321s2, 322s2, and 323s2) of each of the conductive vias 321, 322, and 323 on the electronic component 31.

The circuit structure CS1 may include conductive vias 141, 142, and 143 free from overlapping each of the electronic components 11, 21, 31, and 41 in vertical and horizontal directions. In some embodiments, the conductive vias 141, 142, and 143 are free from overlapping the electronic component 11 perpendicular to the lateral surface 11s3 of the electronic component 11. The conductive vias 141, 142, and 143 may be electrically connected to the conductive vias 121, 122, and/or 123 through the conductive layer 13. The conductive vias 141, 142, and 143 may be electrically connected to the conductive vias 221, 222, and/or 223 through the conductive layer 23.

The conductive via 141 may have a first sidewall 141s1 with a first slope and a second sidewall 141s2 with a second slope, and a first absolute value of the first slope is different from a second absolute value of the second slope. The first absolute value may be smaller than the second absolute value. The first sidewall 141s1 may be closer to the electronic component 11 than the second sidewall 141s2.

The conductive via 143 may have a third sidewall 143s1 with a third slope and an fourth sidewall 143s2 with an fourth slope, and a third absolute value of the third slope is different from an fourth absolute value of the fourth slope. The fourth absolute value may be smaller than the third absolute value. The fourth sidewall 143s2 may be closer to the electronic component 21 than the third sidewall 143s1.

The conductive via 142 may be substantially at the center of the package structure 100. The conductive via 142 may have a fifth sidewall 142s1 with a fifth slope and a sixth sidewall 142s2 with a sixth slope. A fifth absolute value of the fifth slope may be substantially the same as a sixth absolute value of the sixth slope. A first height H11 of the conductive via 142 (or 141, 143) may be greater than a second height H12 of the conductive via 122 (or 121, 123).

FIG. 4B illustrates an enlarged cross-sectional view of a box B12 in FIG. 4.

As shown in FIG. 4B, the first sidewall 141s1 has a first projecting width A41 on the carrier 10 (or the surface 10a2) and the second sidewall 141s2 has a second projecting width A42 on the carrier 10 (or the surface 10a2). Owing to the asymmetrical profile of the conductive via 141, the first projecting width A41 is different from the second projecting width A42. In some embodiments, the first projecting width A41 may be greater than the second projecting width A42.

The third sidewall 143s1 has a third projecting width A45 on the carrier 10 (or the surface 10a2) and the fourth sidewall 143s2 has a fourth projecting width A46 on the carrier 10 (or the surface 10a2). Owing to the asymmetrical profile of the conductive via 143, the third projecting width A45 is different from the fourth projecting width A46. In some embodiments, the fourth projecting width A46 may be greater than the third projecting width A45.

The conductive via 142 may have a fifth sidewall 142s1 and a sixth sidewall 142s2. The fifth sidewall 142s1 has a fifth projecting width A43 on the carrier 10 (or the surface 10a2) and the sixth sidewall 142s2 has a sixth projecting width A44 on the carrier 10 (or the surface 10a2). Owing to the symmetrical profile of the conductive via 142, the fifth projecting width A43 is substantially the same as the sixth projecting width A44.

The conductive vias 141, 142, and 143 may have central axes 141c, 142c, and 143c, respectively. The central axis is an imaginary line that passes through the middle points of the top and bottom surfaces of a conductive via in the cross-sectional view. The central axes 141c and 143c may be non-perpendicular to the carrier 10 (or the surface 10a2). The central axis 142c may be substantially perpendicular to the carrier 10 (or the surface 10a2). The central axes 141c, 142c, and 143c may be non-parallel to each other.

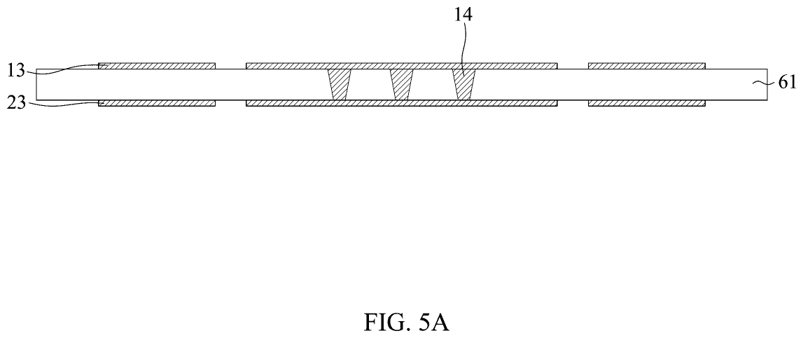

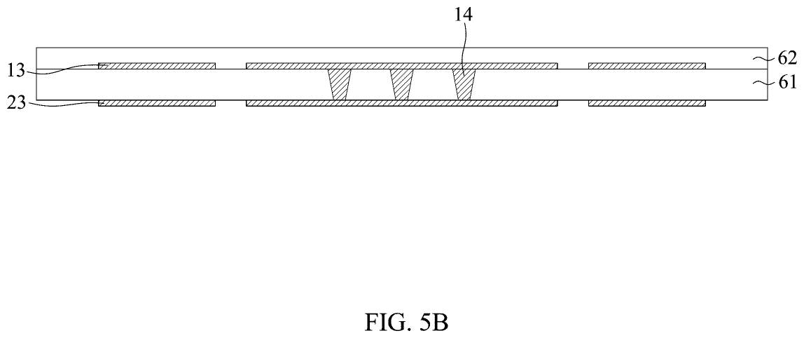

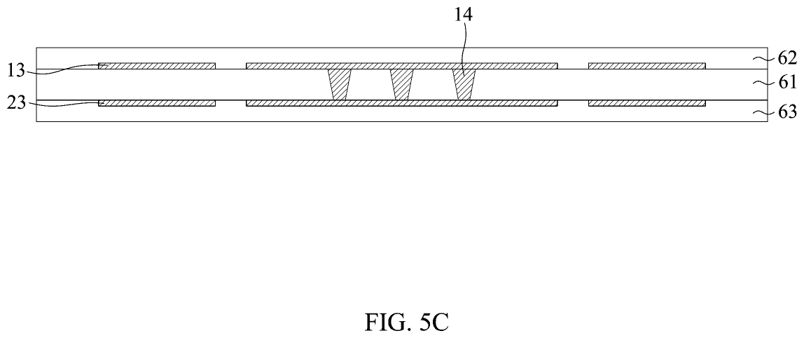

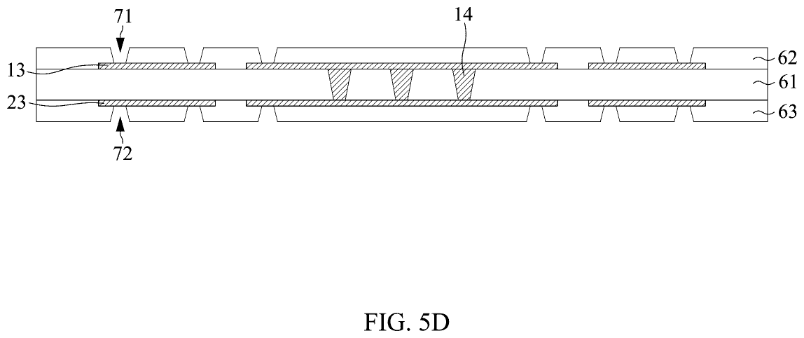

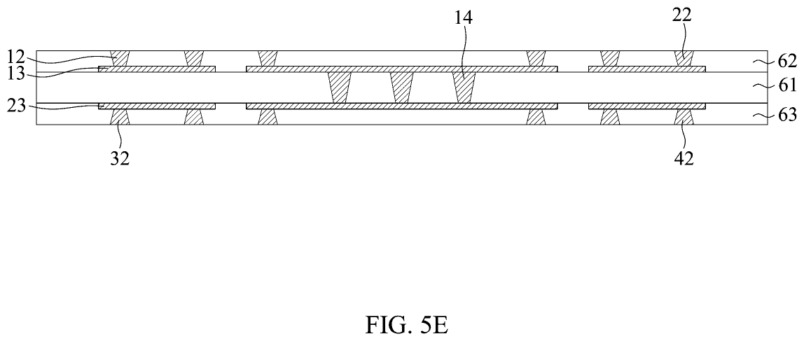

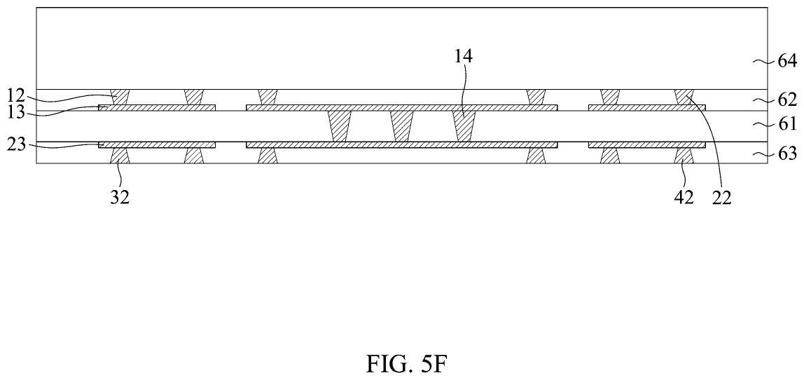

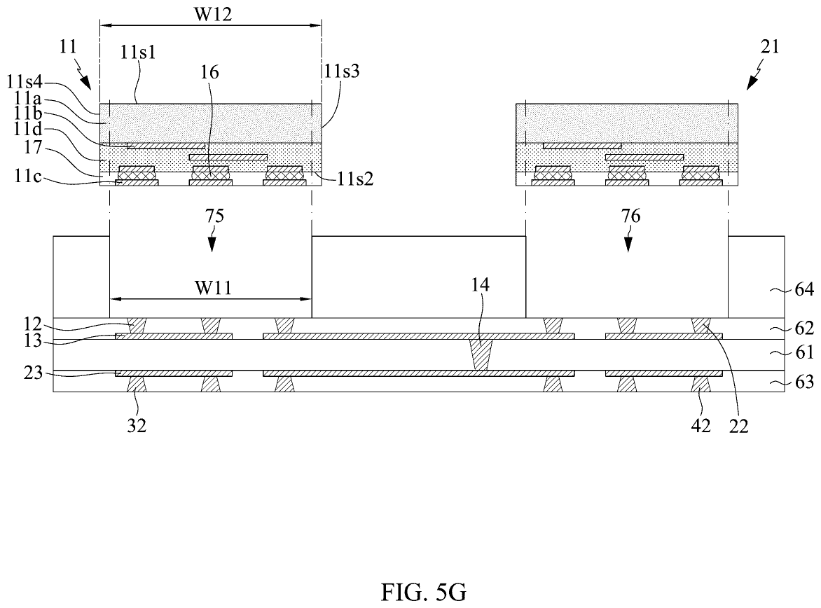

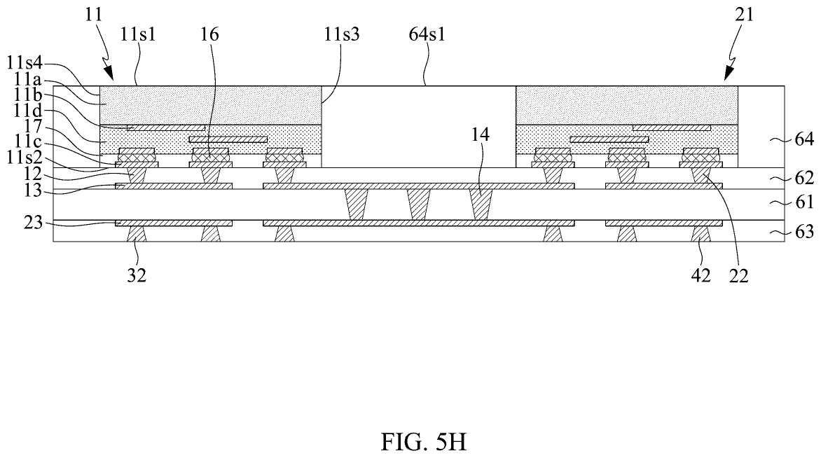

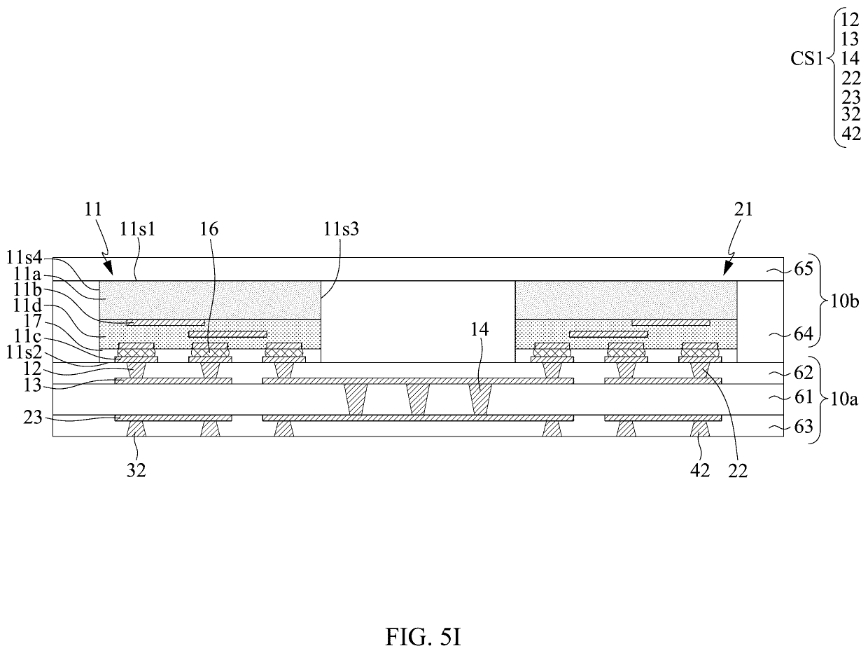

FIGS. 5A, 5B, 5C, 5D, 5E, 5F, 5G, 5H, and 5I illustrate one or more stages of an example of a method for manufacturing a package structure (e.g., the package structure 100) according to some embodiments of the present disclosure.

As shown in FIG. 5A, a material layer 61 may be provided. A plurality of conductive vias 14 may be formed in the material layer 61. A conductive layer 13 and a conductive layer 23 may be formed on opposite sides of the material layer 61. The conductive layer 13 may be electrically connected to conductive layer 23 through the conductive vias 14.

As shown in FIG. 5B, a material layer 62 may be formed over the material layer 61 to cover the conductive layer 13. As shown in FIG. 5C, a material layer 63 may be formed over the material layer 61 to cover the conductive layer 23.

As shown in FIG. 5D, a plurality of holes 71 may be formed in the material layer 62 by, e.g., laser drilling or etching. A plurality of holes 72 may be formed in the material layer 63 by, e.g., laser drilling or etching.

As shown in FIG. 5E, a plurality of conductive vias 12 and a plurality of conductive vias 22 may be formed within the holes 71. A plurality of conductive vias 32 and a plurality of conductive vias 42 may be formed within the holes 72.

As shown in FIG. 5F, a material layer 64 may be formed over the material layer 62 to cover the conductive vias 12 and 32.

The material layers 61, 62, 63, and 64 may be pliable. The material layers 61, 62, 63, and 64 may include a pliable material, a flexible material, or a soft material. The material layers 61, 62, 63, and 64 may include, but are not limited to, thermosetting polymer or thermoplastic polymer. The material layers 61, 62, 63, and 64 may include, but are not limited to, silicone rubber. The material layers 61, 62, 63, and 64 may have substantially the same material to prevent delamination.

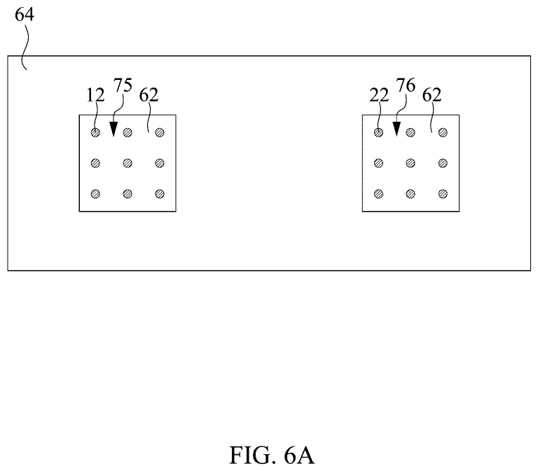

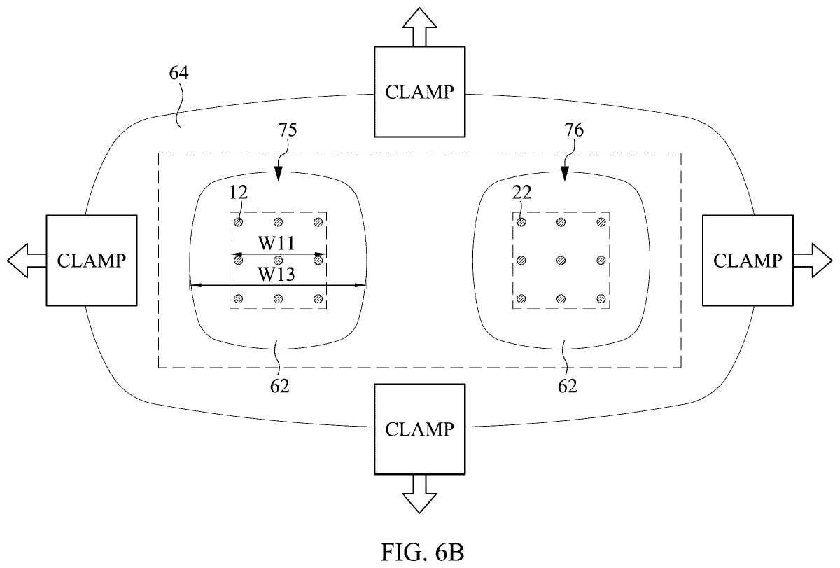

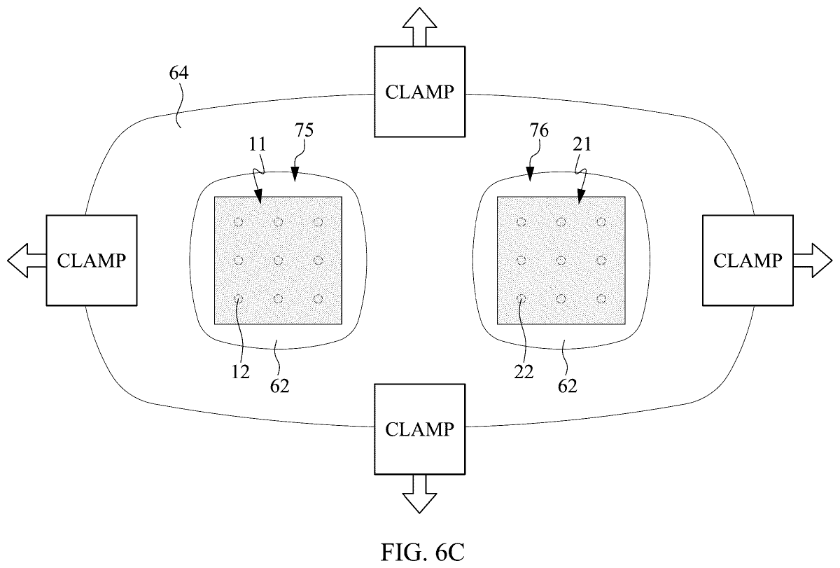

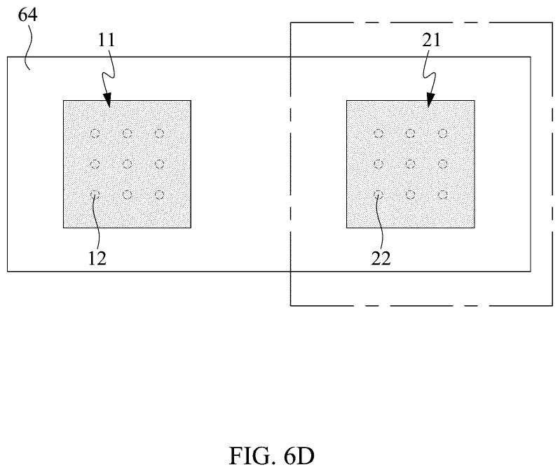

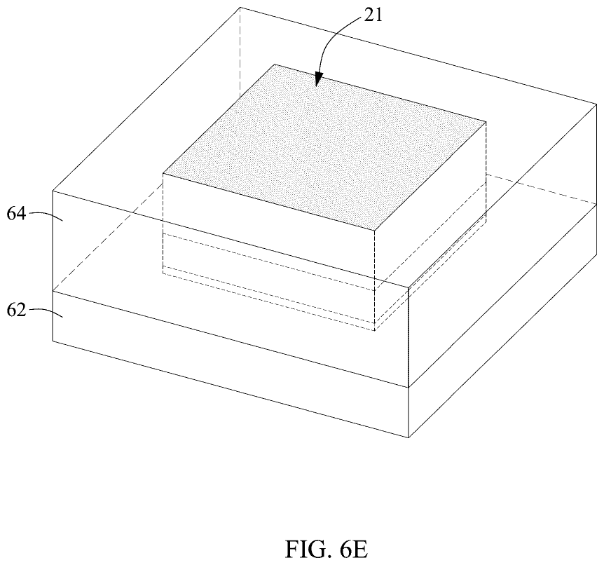

As shown in FIG. 5G, a hole 75 and a hole 76 may be formed in the material layer 64 by laser drilling or etching. The hole 75 and the hole 76 may have a width W11. An electronic component 11 and an electronic component 21 will be mounted on the material layer 62. The electronic component 11 may have a width W12 larger than the width W11 of the hole 75. The original size of the hole 75 and the hole 76 may not be able to accommodate the electronic component 11 and the electronic component 21. Detailed descriptions of the mounting process of the electronic component 11 and the electronic component 21, by temporarily stretching, are discussed in FIGS. 6A, 6B, 6C, 6D, and 6E.

FIGS. 6A, 6B, 6C, and 6D each represent a top view of a structure in FIGS. 5G and 5H.

FIG. 6A shows the top view of the holes 75 and 76. FIG. 6B shows that the material layer 64 along with the material layers 61, 62, and 63 are stretched to enlarge the holes 75 and 76 by a plurality of clamps. The holes 75 and 76 may have an enlarged width W13. The dashed line shows the original size of the material layer 64 and the holes 75 and 76 prior to the stretching. Owing to the stretching, the conductive vias 12 may be deformed, and the pitches of the conductive vias 12 and the conductive vias 22 may be larger than the original pitches.

As shown in FIG. 6C, the enlarged width W13 is larger than the width W12 of the electronic component 11, such that the holes 75 and 76 can accommodate the electronic component 11 and the electronic component 21. The electronic component 11 and the electronic component 21 may be mounted to the material layer 62. The conductive pads 11c of the electronic component 11 may be mounted to the conductive vias 12. The sidewall of the hole 75 may be spaced apart from the electronic component 11 when the material layer 64 is stretched by the clamps.

As shown in FIG. 6D, the clamps are removed, the material layers 61, 62, 63 elastically recover. As such, the electronic component 11 and the electronic component 21 may be in contact with the material layer 64. FIG. 6E illustrates a perspective view of a structure in FIG. 6D. The electronic component 21 may be surrounded by the material layer 64. The material layer 64 is formed prior to the mounting of the electronic component 11 and the electronic component 21. The material layer 64 (or a part of the portion 10b) may be detachably connected to the electronic component 11 and the electronic component 21.

As shown in FIG. 5H, the electronic component 11 and the electronic component 21 may be mounted to the material layer 62. An upper surface 11s1 of the electronic component 11 and an upper surface 64s1 of the material layer 64 may be substantially at the same elevation. In some embodiments, the upper surface 11s1 and the upper surface 64s1 may be substantially coplanar.

In some embodiments, the conductive vias 12 may be metallically bonded to the conductive pads 11c. Even if the clamps are removed, the deformation of the conductive vias 12 induced by the stretching may partially remain because of the bonding with the conductive pads 11c. In some embodiments, the conductive vias 12 may have the same tilted profile (or asymmetrical profile) as the conductive vias 121, 122, and 123 in FIGS. 4 and 4A. In some embodiments, the conductive vias 32 may have the same tilted profile (or asymmetrical profile) as the conductive vias 321, 322, and 323 in FIG. 4. In some embodiments, the conductive vias 14 may have the same tilted profile (or asymmetrical profile) as the conductive vias 141, 142, and 143 in FIGS. 4 and 4B.

As shown in FIG. 5I, a material layer 65 may be formed over the material layer 64 to cover the electronic component 11 and the electronic component 21. The material layers 61, 62, and 63 may be referred to as a portion 10a of a carrier 10. The material layers 64 and 65 may be referred to as a portion 10b of the carrier 10. The conductive vias 12, the conductive layer 13, the conductive vias 14, the conductive vias 22, the conductive layer 23 may be referred to as a circuit structure CS1.

In some embodiments, processes similar to those in FIGS. 5F, 5G, and 5I may be applied to the opposite side of a structure, as shown in FIG. 5I, to form the package structure 100. In some embodiments, a material layer may be applied to the opposite side prior to the stretching and mounting processes, and the electronic components 11, 21, 31, and 41 may be mounted to the portion 10a in the same process.

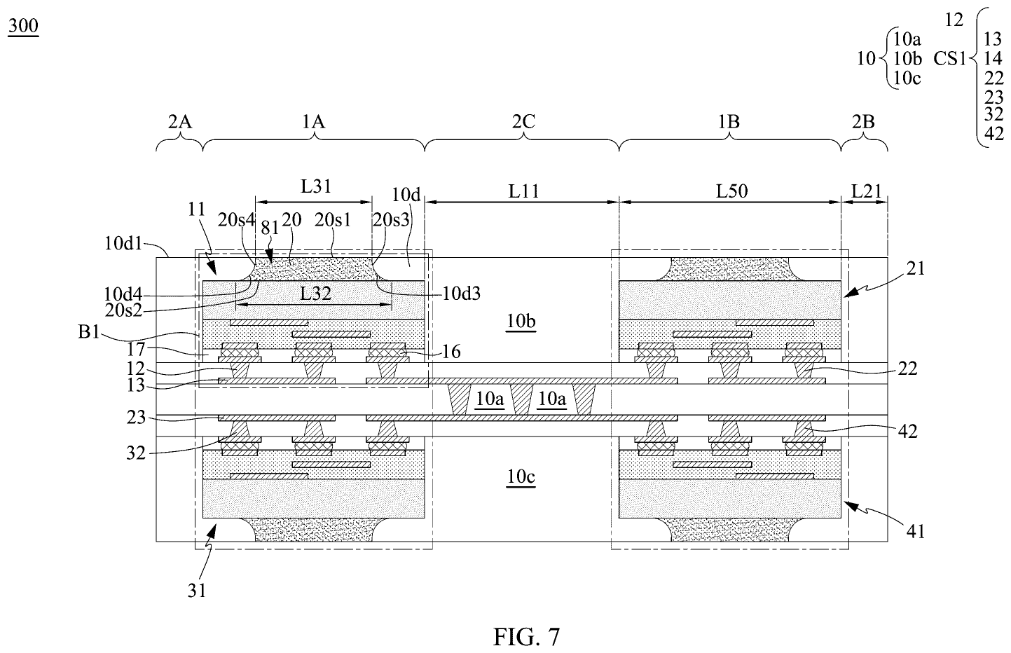

FIG. 7 is a cross-sectional view of a package structure 300 according to some embodiments of the present disclosure. The package structure 300 in FIG. 7 is similar to the package structure 100 in FIG. 1. Therefore, some detailed descriptions may refer to corresponding preceding paragraphs and are not repeated hereinafter for conciseness, with differences therebetween as follows.

The carrier 10 of the package structure 300 may define a zone 81 above the upper surface 11s1 of the electronic component 11. The zone 81 may be taper in a direction away from the electronic component 11. The zone 81 may be above each of the electronic components 21, 31, and 41. The package structure 300 may include an insulating layer 20 disposed in the zone 81. The insulating layer 20 may be disposed over each of the electronic components 11, 21, 31, and 41. The relationship between the insulating layer 20 and the electronic components 11, 21, 31, and 41 is similar or the same. The insulating layer 20 may be disposed above the upper surface 11s1 of the electronic component 11 and in contact with the carrier 10. A bottom surface 20s2 of the insulating layer 20 may be in contact with the electronic component 11.

The carrier 10 may include a portion 10d surrounding the insulating layer 20. A top surface 20s1 of the insulating layer 20 and a top surface 10d1 of the portion 10d of the carrier 10 may be substantially coplanar. The insulating layer 20 may be inseparably connected to the electronic component 11. The portion 10d may have a first lateral surface 10d3 defining the shape of the first curved lateral surface 20s3. The portion 10d may have a second lateral surface 10d4 defining the shape of the second curved lateral surface 20s4.

In some embodiments, the insulating layer 20 may be defined by the profile of the portion 10d. During the mounting process of the electronic component 11, the carrier 10 may be stretched by a deformation force to enlarge the space for accommodating the electronic component 11. Once the deformation force is removed, the carrier 10 may elastically recover. A portion of the carrier 10 higher than the electronic component 11 may be squeezed to form a ledge (e.g., the portion 10d) over the electronic component 11. An insulating material may be formed in a space defined by the portion 10d to form the insulating layer 20. The insulating layer 20 may taper in a direction away from the electronic component 11. The insulating layer 20 may have a first curved lateral surface 20s3 and a second curved lateral surface 20s4 opposite to the first curved lateral surface 20s3. The insulating layer 20 may have a length L31 along the top surface 20s1 and a length L32 along the bottom surface 20s2. The length L32 may be different from the length L31. In some embodiments, the length L32 may be larger than the length L31.

In some embodiments, a material of the insulating layer 20 may be substantially the same as a material of the carrier 10. In some embodiments, the insulating layer 20 may include a material that has sufficient bondability with the carrier 10. In some embodiments, a material of the insulating layer 20 may have an Si functional group. In some embodiments, a material of the insulating layer 20 may include Silane.

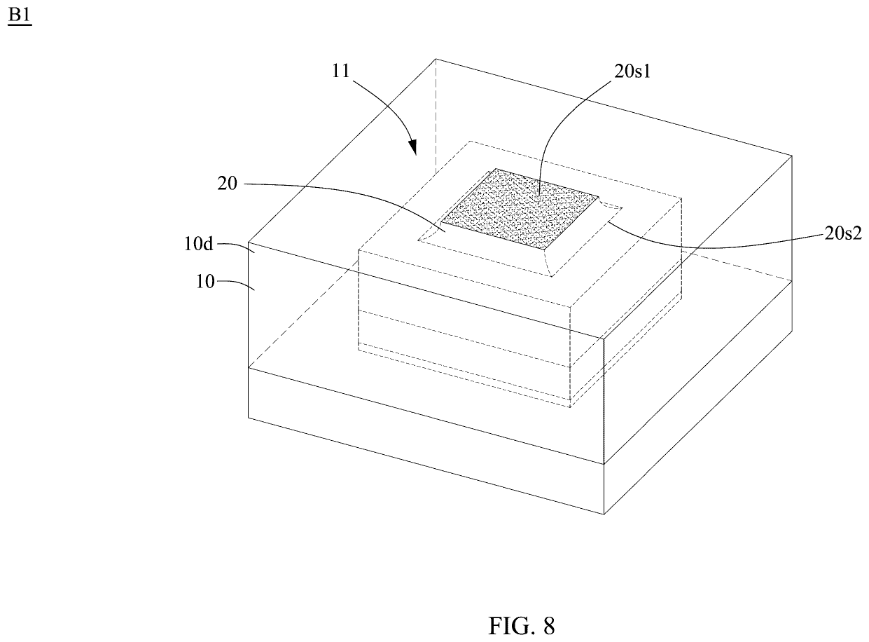

FIG. 8 is a perspective view of a box B1 in FIG. 7. As shown in FIG. 8, the insulating layer 20 may have a curved slope. The area of the top surface 20s1 of the insulating layer 20 may be smaller than that of the bottom surface 20s2 of the insulating layer 20.

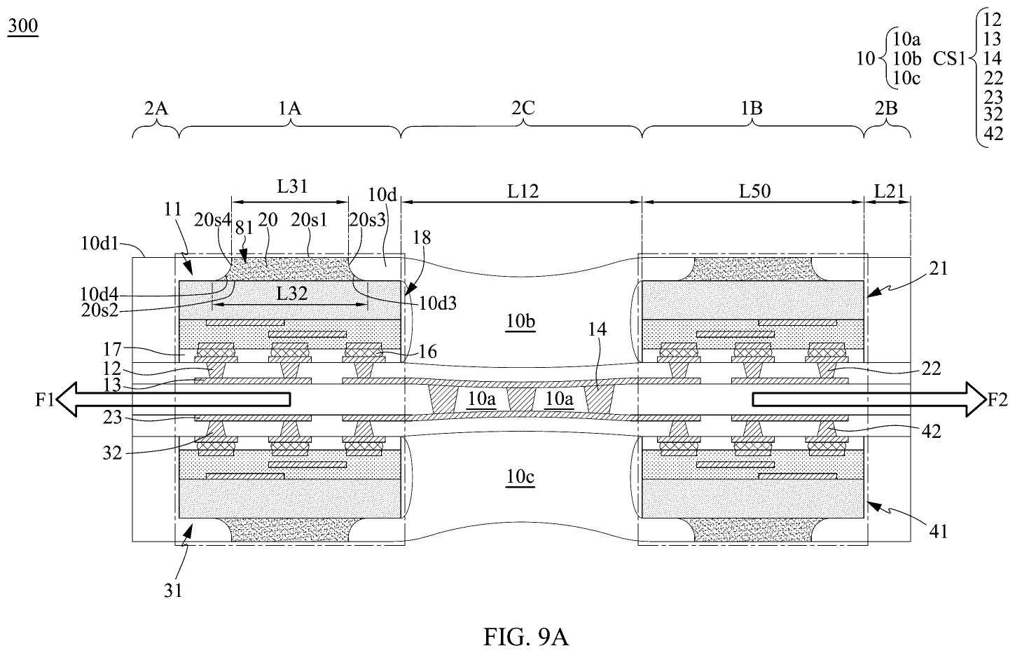

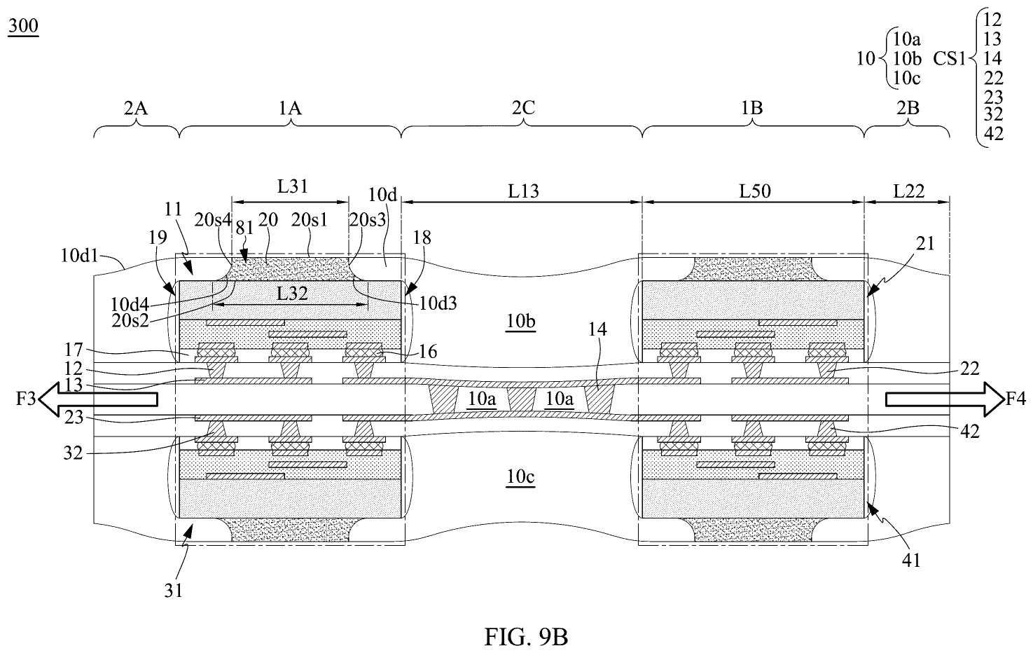

FIG. 9A is a cross-sectional view of a package structure (e.g., the package structure 300) being applied with a deformation force according to some embodiments of the present disclosure. The package structure 300 in FIG. 9A is similar to the package structure 100 in FIG. 2A. The package structure 300 may be in a stretching state. Therefore, some detailed descriptions may refer to corresponding preceding paragraphs and are not repeated hereinafter for conciseness, with differences therebetween as follows.

As previously discussed in the descriptions of FIG. 7, the package structure 300 further includes the insulating layer 20 disposed over each of the electronic components 11, 21, 31, and 41. The insulating layer 20 may be comprised in the regions 1A and 1B. The insulating layer 20 may be tightly connected to the portion 10d of the carrier 10 without any delamination. The lengths L31 and L32 of the insulating layer 20 while the package structure 300 is stretched may be substantially the same as those while the package structure 300 is in the initial state.

FIG. 9B is a cross-sectional view of a package structure (e.g., the package structure 300) being applied with a deformation force according to some embodiments of the present disclosure. The package structure 300 in FIG. 9B is similar to the package structure 100 in FIG. 2B. The package structure 300 may be in a stretching state. Therefore, some detailed descriptions may refer to corresponding preceding paragraphs and are not repeated hereinafter for conciseness, with differences therebetween as follows.

As previously discussed in the descriptions of FIG. 7, the package structure 300 further includes the insulating layer 20 disposed over each of the electronic components 11, 21, 31, and 41. The insulating layer 20 may be comprised in the regions 1A and 1B. The insulating layer 20 may be tightly connected to the portion 10d of the carrier 10 without any delamination. The lengths L31 and L32 of the insulating layer 20 while the package structure 300 is stretched may be substantially the same as those while the package structure 300 is in the initial state.

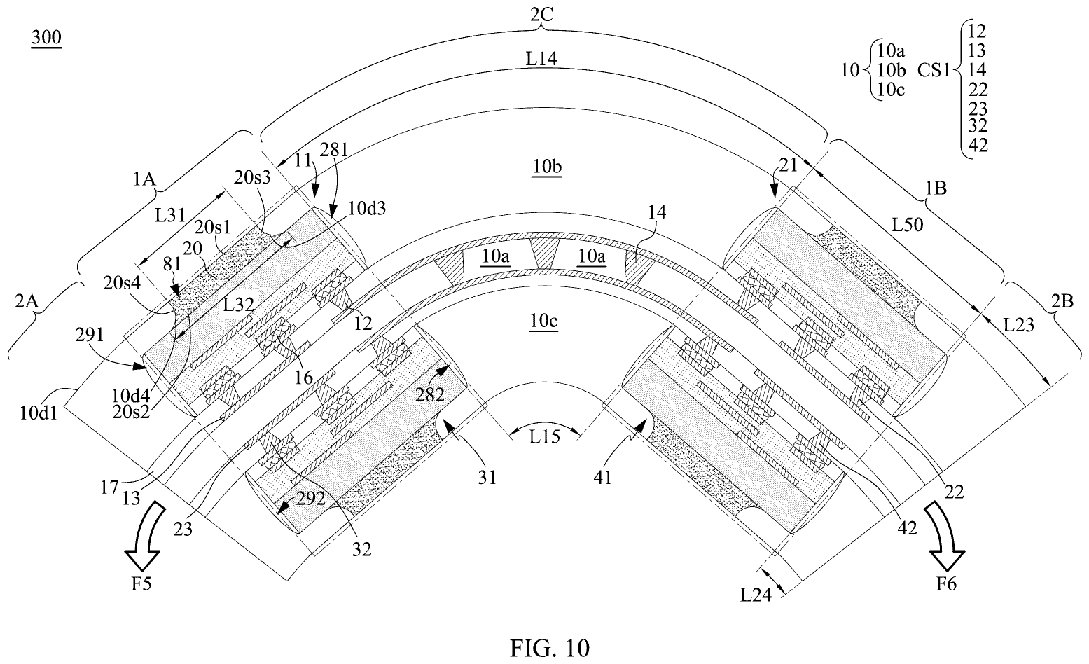

FIG. 10 is a cross-sectional view of a package structure (e.g., the package structure 300) being applied with a deformation force according to some embodiments of the present disclosure. The package structure 300 in FIG. 10 is similar to the package structure 100 in FIG. 3. The package structure 300 may be in a folding state. Therefore, some detailed descriptions may refer to corresponding preceding paragraphs and are not repeated hereinafter for conciseness, with differences therebetween as follows.

As previously discussed in the descriptions of FIG. 7, the package structure 300 further includes the insulating layer 20 disposed over each of the electronic components 11, 21, 31, and 41. The insulating layer 20 may be comprised in the regions 1A and 1B. The insulating layer 20 may be tightly connected to the portion 10d of the carrier 10 without any delamination. The lengths L31 and L32 of the insulating layer 20 while the package structure 300 is folded may be substantially the same as those while the package structure 300 is in the initial state.

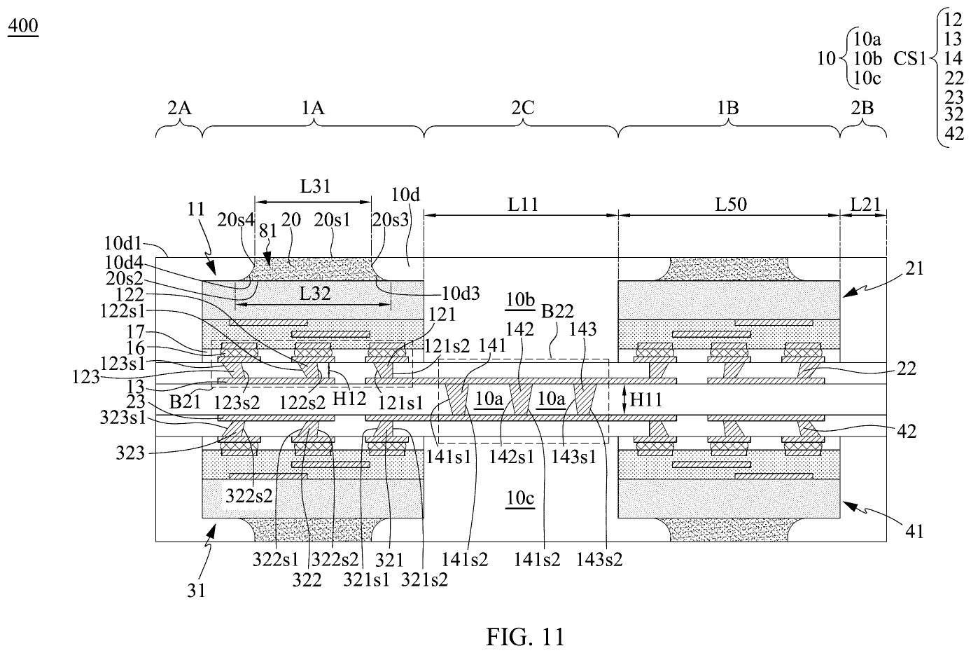

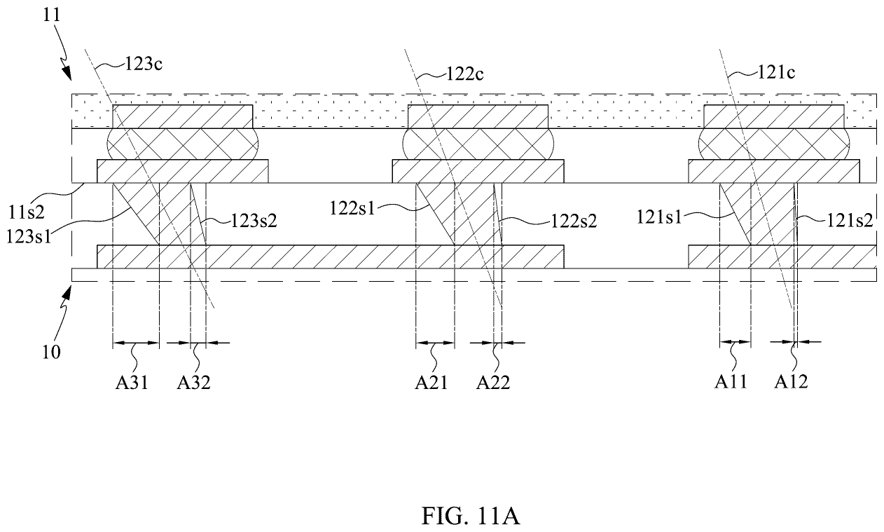

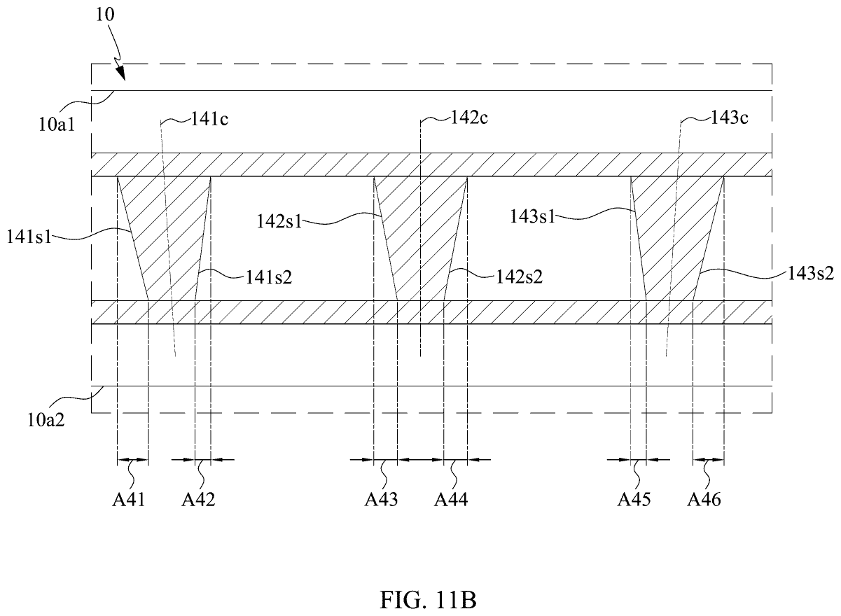

FIG. 11 is a cross-sectional view of a package structure 400 according to some embodiments of the present disclosure. FIG. 11A illustrates an enlarged cross-sectional view of a box B21 in FIG. 11. FIG. 11B illustrates an enlarged cross-sectional view of a box B22 in FIG. 11. The package structure 400 in FIGS. 11, 11A, and 11B is similar to the package structure 200 in FIGS. 4, 4A, and 4B. Therefore, some detailed descriptions may refer to corresponding preceding paragraphs and are not repeated hereinafter for conciseness, with differences therebetween as follows.

As previously discussed in the descriptions of FIG. 7, the package structure 300 further includes the insulating layer 20 disposed over each of the electronic components 11, 21, 31, and 41. The insulating layer 20 may be comprised in the regions 1A and 1B. The insulating layer 20 may overlap the conductive vias 121, 122, and 123 in a vertical direction. The insulating layer 20 may overlap the conductive vias 121, 122, and 123 in a direction perpendicular to the top surface 20s1 or the bottom surface 20s2. The insulating layer 20 may overlap the conductive vias 321, 322, and 323 in a vertical direction. The insulating layer 20 may overlap the conductive vias 321, 322, and 323 in a direction perpendicular to the top surface 20s1 or the bottom surface 20s2.

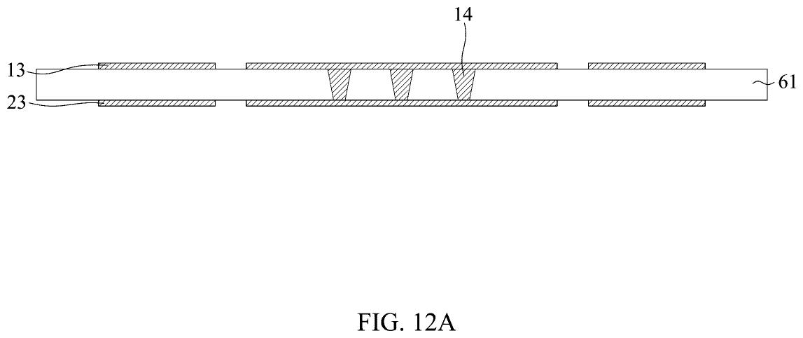

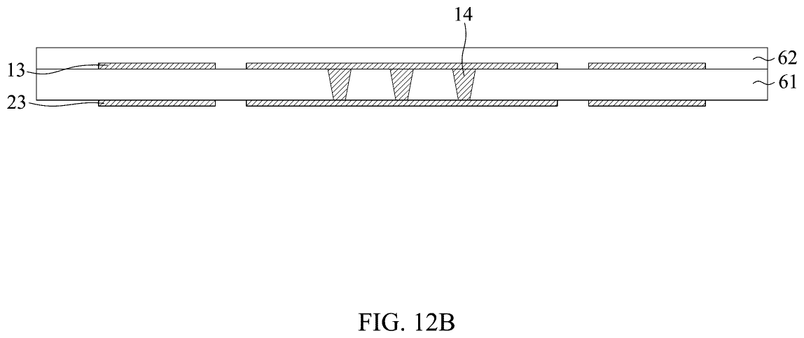

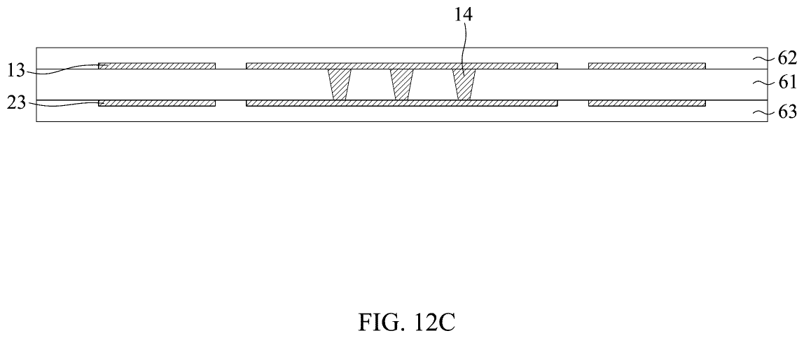

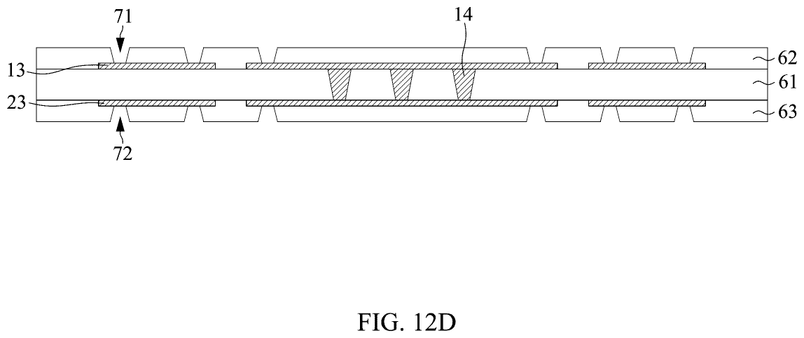

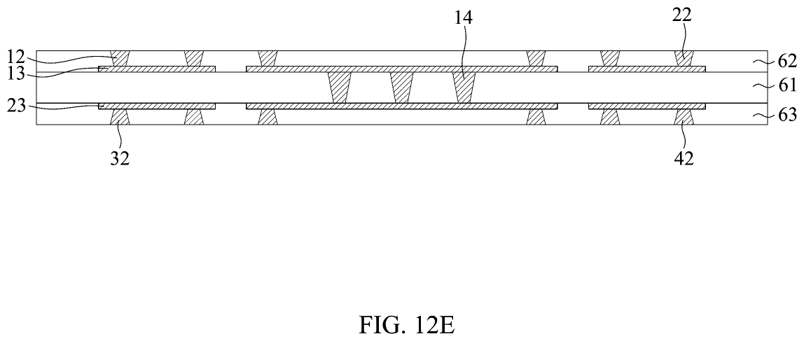

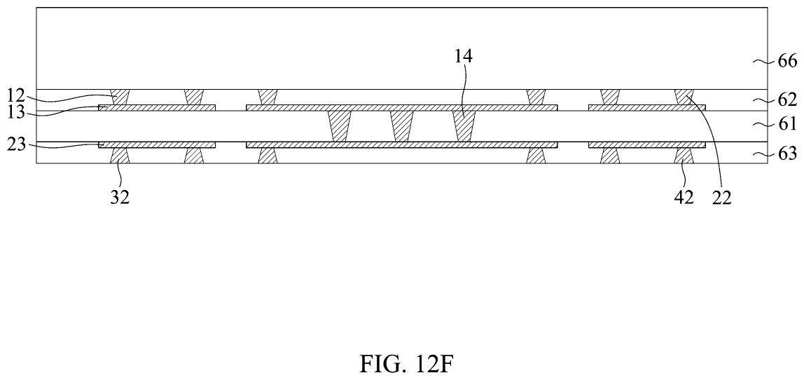

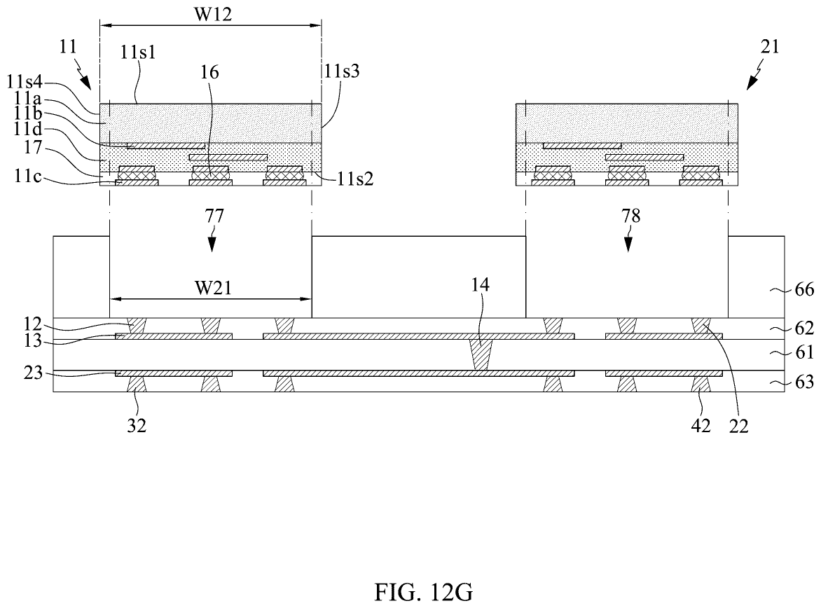

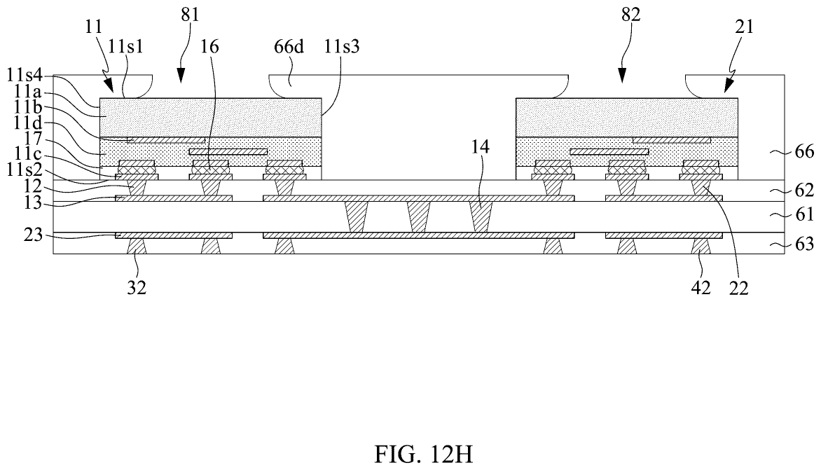

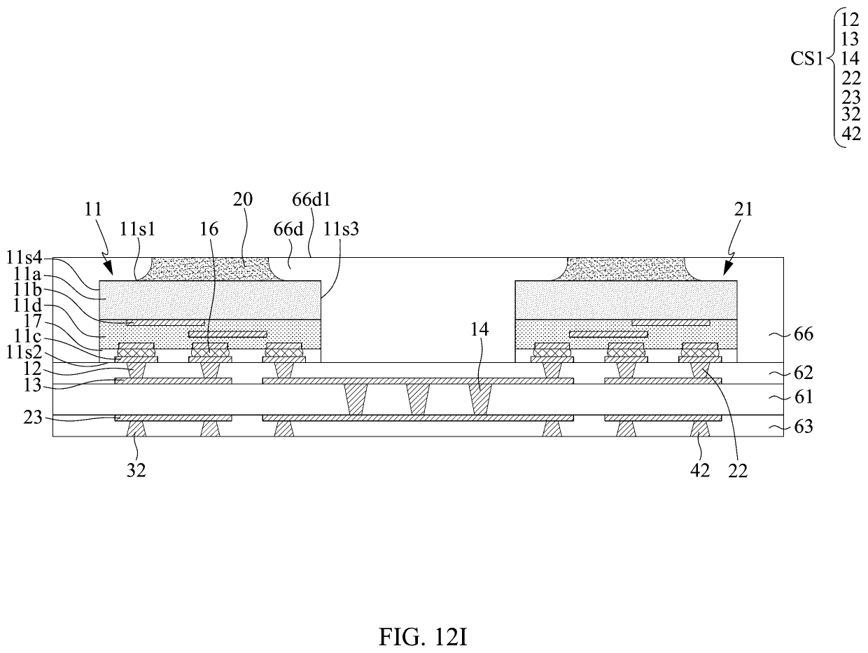

FIGS. 12A, 12B, 12C, 12D, 12E, 12F, 12G, 12H, and 12I illustrate one or more stages of an example of a method for manufacturing a package structure (e.g., the package structure 300) according to some embodiments of the present disclosure.

FIGS. 12A, 12B, 12C, 12D, and 12E may respectively correspond to FIGS. 5A, 5B, 5C, 5D, and 5E. Therefore, some detailed descriptions may refer to corresponding preceding paragraphs and are not repeated hereinafter for conciseness.

As shown in FIG. 12F, a material layer 66 may be formed over the material layer 62 to cover the conductive vias 12 and 32. The thickness of the material layer 66 may be greater than that of the material layer 64.

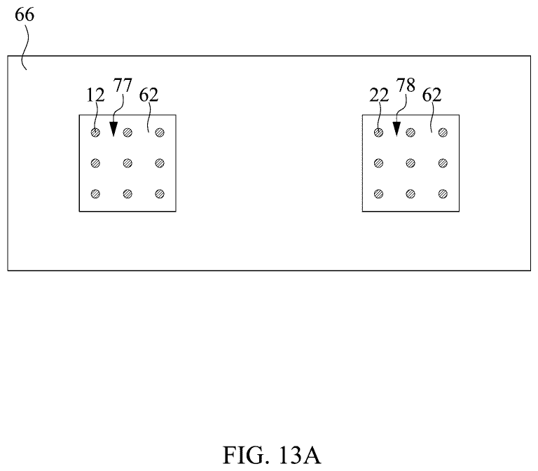

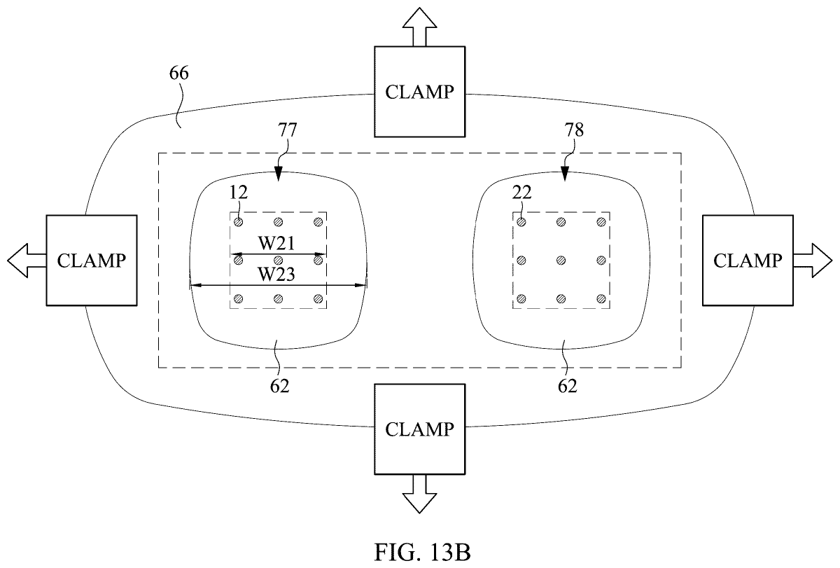

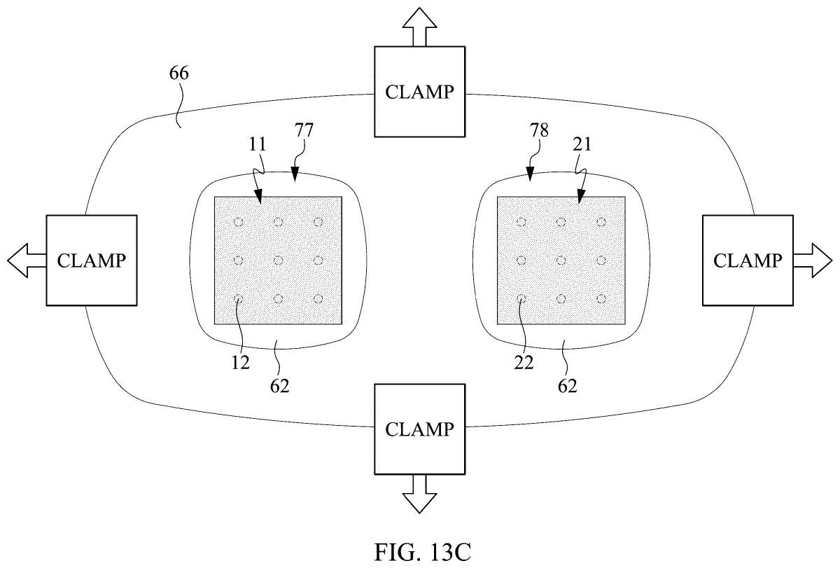

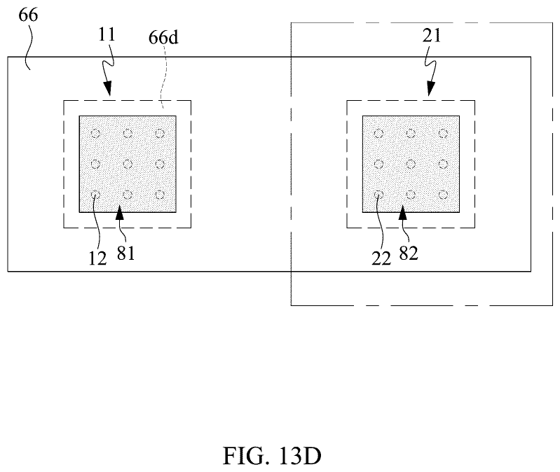

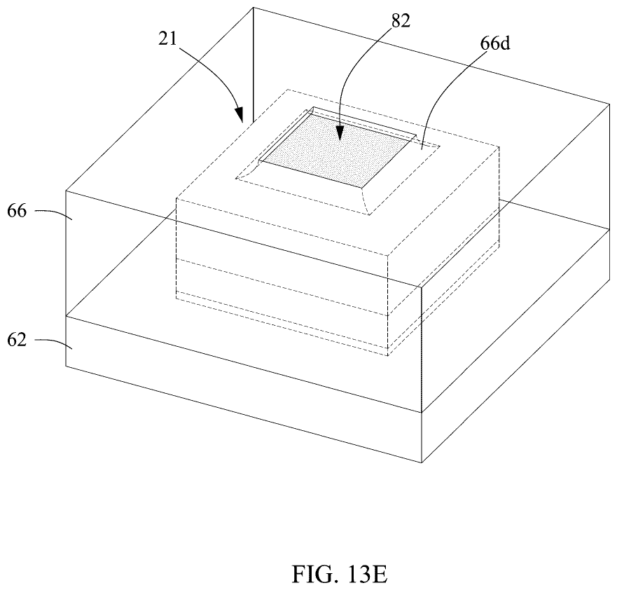

As shown in FIG. 12G, a hole 77 and a hole 78 may be formed in the material layer 66 by laser drilling or etching. The hole 77 may have a width W21. An electronic component 11 and an electronic component 21 will be mounted on the material layer 62. The electronic component 11 may have a width W12 larger than the width W21 of the hole 75. The original size of the hole 77 may not be able to accommodate the electronic component 11. Detailed descriptions of the mounting process of the electronic component 11 and the electronic component 21, by temporarily stretching, are discussed in FIGS. 13A, 13B, 13C, 13D, and 13E.

FIGS. 13A, 13B, 13C, and 13D each represent a top view of a structure in FIGS. 12G and 12H.

FIG. 13A shows the top view of the holes 77 and 78. FIG. 13B shows that the material layer 66 along with the material layers 61, 62, and 63 are stretched to enlarge the holes 77 and 78 by a plurality of clamps. The holes 77 and 78 may have an enlarged width W23. The dashed line shows the original size of the material layer 66 and the holes 77 and 78 prior to the stretching. Owing to the stretching, the conductive vias 12 may be deformed and the pitches of the conductive vias 12 and the conductive vias 22 may be larger than the original pitches.

As shown in FIG. 13C, the enlarged width W23 is larger than the width W12 of the electronic component 11, such that the holes 77 and 78 can accommodate the electronic component 11 and the electronic component 21. The electronic component 11 and the electronic component 21 may be mounted to the material layer 62. The conductive pads 11c of the electronic component 11 may be mounted to the conductive vias 12. The sidewall of the hole 77 may be spaced apart from the electronic component 11 when the material layer 66 is stretched by the clamps.

As shown in FIG. 13D, the clamps are removed, the material layers 61, 62, 63, and 66 elastically recover. As such, the electronic component 11 and the electronic component 21 may be in contact with the material layer 66. FIG. 13E illustrates a perspective view of a structure in FIG. 13D. A portion of the material layer 66 higher than the electronic component 11 and the electronic component 21 may be squeezed to form a ledge (e.g., a portion) 66d over the electronic component 11 and the electronic component 21.

In some embodiments, a zone (or a hole) 81 may be formed over the electronic component 11 and a zone (or a hole) 82 may be formed over the electronic component 21. The electronic component 11 may be exposed by the zone 81. The electronic component 21 may be exposed by the hole 82.

The electronic component 21 may be surrounded by the material layer 66. The material layer 66 is formed prior to the mounting of the electronic component 11 and the electronic component 21. The material layer 66 may be detachably connected to the electronic component 11 and the electronic component 21.

As shown in FIG. 12H, the electronic component 11 and the electronic component 21 may be mounted to the material layer 62. An upper surface 11s1 of the electronic component 11 may be lower than an upper surface 66s1 of the material layer 66. The portion 66d of the material layer 66 may have a round or curved shape. The round or curved shape may be induced by the compression from the corners of the electronic component 11 or the electronic component 21.

In some embodiments, the conductive vias 12 may be metallically bonded to the conductive pads 11c. Even if the clamps are removed, the deformation of the conductive vias 12 induced by the stretching may partially remain because of the bonding with the conductive pads 11c. In some embodiments, the conductive vias 12 may have the same tilted profile (or asymmetrical profile) as the conductive vias 121, 122, and 123 in FIGS. 11 and 11A. In some embodiments, the conductive vias 32 may have the same tilted profile (or asymmetrical profile) as the conductive vias 321, 322, and 323 in FIG. 11. In some embodiments, the conductive vias 14 may have the same tilted profile (or asymmetrical profile) as the conductive vias 141, 142, and 143 in FIGS. 11 and 11B.

As shown in FIG. 12I, an insulating layer 20 may be formed in the zones 81 and 82. The insulating layer 20 may protect the electronic components 11 and 21. The insulating layer 20 may taper in a direction away from the electronic component 11. The insulating layer 20 may have a first curved lateral surface 20s3 and a second curved lateral surface 20s4. The insulating layer 20 may have a top surface 20s1 and a bottom surface 20s2 opposite to the top surface 20s1. The top surface 20s1 and a top surface 66d1 of the portion 66d may be at substantially the same height. The top surface 20s1 and a top surface 66d1 of the portion 66d may be substantially coplanar.

The material layers 61, 62, and 63 may be referred to as a portion 10a of a carrier 10. The material layer 66 may be referred to as a portion 10b of the carrier 10. The portion 66d of the material layer 66 may be referred to as a portion 10d of the carrier 10. The conductive vias 12, the conductive layer 13, the conductive vias 14, the conductive vias 22, the conductive layer 23 may be referred to as a circuit structure CS1.

In some embodiments, processes similar to those in FIGS. 12F, 12G, and 12I may be applied to the opposite side of a structure as shown in FIG. 12I to form the package structure 300. In some embodiments, a material layer may be applied to the opposite side prior to the stretching and mounting processes, and the electronic components 11, 21, 31, and 41 may be mounted to the portion 10a in the same process.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” perpendicular can refer to a range of angular variation relative to 90°that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural references unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package structure, comprising:
a first electronic component having an upper surface; and
a flexible carrier adjustably fastening the first electronic component;
wherein the flexible carrier defines a zone above the upper surface of the first electronic component and tapering in a direction away from the first electronic component.

2. The package structure of claim 1, further comprising an insulating layer disposed in the zone.

3. The package structure of claim 2, wherein the insulating layer has a curved lateral surface.

4. The package structure of claim 2, wherein a material of the insulating layer is substantially the same as a material of the flexible carrier.

5. The package structure of claim 1, wherein the flexible carrier has a first inner sidewall and a second inner sidewall facing the first electronic component, and a distance between the first inner sidewall and the second inner sidewall is adjustable based on a width of the first electronic component.

6. The package structure of claim 1, wherein the flexible carrier comprises a first portion disposed below the first electronic component and a second portion encapsulating the first electronic component.

7. The package structure of claim 6, further comprising a second electronic component disposed below the first portion, and a circuit structure embedded in the first portion, wherein the first electronic component is electrically connected to the second electronic component through the circuit structure.

8. The package structure of claim 7, wherein the circuit structure comprises a plurality of first conductive vias in contact with a plurality of first conductive pads of the first electronic component and a plurality of second conductive vias in contact with a plurality of second conductive pads of the second electronic component, wherein the first conductive vias taper in a direction opposite to the second conductive vias.

9. The package structure of claim 1, further comprising:
a first region having a first pliability, wherein the first electronic component is comprised in the first region; and
a second region adjacent to the first region, the second region having a second pliability greater than the first pliability.

10. The package structure of claim 9, wherein, when the package structure is folded or stretched, a curvature of the second region may be greater than a curvature of the first region.

11. A package structure, comprising:
a flexible carrier;
a first electronic component encapsulated by the flexible carrier; and
a first conductive via disposed below and electrically connected to the first electronic component,
wherein the first conductive via has a first sidewall and a second sidewall, and
wherein, in a cross-sectional view, a first projecting width of the first sidewall on the first electronic component is different from a second projecting width of the second sidewall on the first electronic component.

12. The package structure of claim 11, wherein, in the cross-sectional view, the first sidewall is closer to a lateral surface of the first electronic component than the second sidewall, wherein the first projecting width is greater than the second projecting width.

13. The package structure of claim 12, further comprising:
a second conductive via free from overlapping the first electronic component in a direction parallel to the lateral surface of the first electronic component,
wherein the second conductive via has a third sidewall and a fourth sidewall,
wherein, in the cross-sectional view, a third projecting width of the third sidewall on the flexible carrier is different from a fourth projecting width of the fourth sidewall on the flexible carrier.

14. The package structure of claim 11, wherein, in the cross-sectional view, the first conductive via has a first central axis non-perpendicular to a lower surface of the first electronic component.

15. The package structure of claim 14, further comprising a third conductive via adjacent to the first conductive via and electrically connected to the first electronic component, wherein, in the cross-sectional view, the third conductive via has a second central axis non-parallel to the first central axis.

16. A package structure, comprising:
a flexible carrier; and
a first electronic component encapsulated by the flexible carrier,
wherein, when the package structure is applied with a deformation force, the first electronic component and the flexible carrier define a first cavity therebetween.

17. The package structure of claim 16, further comprising a circuit structure embedded in the flexible carrier and electrically connected to the first electronic component.

18. The package structure of claim 16, wherein, during the application of the deformation force, the flexible carrier has a first portion spaced apart from the first electronic component by the first cavity.

19. The package structure of claim 18, wherein, when the deformation force is removed, the first portion is in direct contact with the first electronic component.

20. The package structure of claim 16, wherein the first electronic component is surrounded by the first cavity.
